(19) United States
(12) Patent Application Publication
(10) Pub. No.: US 2010/0132765 A1
(43) Pub. Date: Jun. 3, 2010

(54) HERMETICALLY SEALED SOLAR CELLS

(76) Inventors: Brian H. Cumpston, Pleasanton, CA (US); Benyamin Buller, Sylvania, OH (US)

Correspondence Address: JONES DAY, 222 EAST 41ST ST, NEW YORK, NY, 10017, US

(21) Appl. No.: 12/649,147

(22) Filed: Dec. 29, 2009

Related U.S. Application Data
(63) Continuation-in-part of application No. 12/301,611.
Application No. 12/301,611 is a continuation-in-part of application No. 11/437,928, filed on May 19, 2006.

(51) Int. Cl. H01L 31/042; H01L 31/00

(52) U.S. Cl. 136/249; 136/259; 136/255; 136/256; 136/244

(57) ABSTRACT

An elongated solar cell unit comprising (i) a substrate, (ii) one or more solar cells disposed on the substrate, (iii) a transparent casing disposed onto the one or more solar cells, the transparent nonplanar casing having a first end and a second end; and (iv) a first sealant cap that is hermetically sealed to the first end of the transparent nonplanar casing is provided. A solar cell unit comprising (i) a substrate, (ii) one or more bifacial or omnifacial solar cells disposed on the substrate, (iii) a transparent casing disposed onto the one or more bifacial or omnifacial solar cells, the transparent nonplanar casing having a first end and a second end and (iv) a first sealant cap that is hermetically sealed to the first end of the transparent nonplanar casing is provided.

### CROSS REFERENCE TO RELATED APPLICATIONS

This application claims priority to U.S. patent application Ser. No. 11/437,928, filed on May 19, 2006, which is hereby incorporated by reference herein in its entirety. This application is a continuation-in-part of U.S. patent application Ser. No. 12/301,611, filed as a National Stage of PCT/US2007/011920, which is hereby incorporated by reference herein in its entirety.

### 1. FIELD

The present disclosure relates to hermetically sealed solar cell units comprising solar cells for converting solar energy into electrical energy.

### 2. BACKGROUND

Solar cells are typically fabricated as separate physical entities with light gathering surface areas on the order of 4-6 cm² or larger. For this reason, it is standard practice for power generating applications to mount the cells in a flat array on a supporting substrate or panel so that their light gathering surfaces provide an approximation of a single large light gathering surface. Also, since each cell itself generates only a small amount of power, the required voltage and/or current is realized by interconnecting the cells of the array in a series and/or parallel matrix.

A conventional prior art solar cell structure is shown in FIG. 1. Because of the large range in the thickness of the different layers, they are depicted schematically. Moreover, FIG. 1 is highly schematic so that it represents the features of both “thick-film” solar cells and “thin-film” solar cells. In general, solar cells that use an indirect band gap material to absorb light are typically configured as “thick-film” solar cells because a thick film of the absorber layer is required to absorb a sufficient amount of light. Solar cells that use a direct band gap material to absorb light are typically configured as “thin-film” solar cells because only a thin layer of the direct band-gap material is needed to absorb a sufficient amount of light.

The arrows at the top of FIG. 1 show the source of direct solar illumination on the cell. Layer 102 is the substrate. Glass or metal is a common substrate. In thin-film solar cells, substrate 102 can be-a polymer-based backing, metal, or glass. In some instances, there is an encapsulation layer (not shown) coating substrate 102. Layer 104 is the back electrical contact for the solar cell.

Layer 106 is the semiconductor absorber layer. Back electrical contact 104 makes ohmic contact with absorber layer 106. In many but not all cases, absorber layer 106 is a p-type semiconductor. Absorber layer 106 is thick enough to absorb light. Layer 108 is the semiconductor junction partner—that, together with semiconductor absorber layer 106, completes the formation of a p-n junction. A p-n junction is a common type of junction found in solar cells. In p-n junction based solar cells, when semiconductor absorber layer 106 is a p-type doped material, junction partner 108 is an n-type doped material. Conversely, when semiconductor absorber layer 106 is an n-type doped material, junction partner 108 is a p-type doped material. Generally, junction partner 108 is much thinner than absorber layer 106. For example, in some instances junction partner 108 has a thickness of about 0.05 microns. Junction partner 108 is highly transparent to solar radiation. Junction partner 108 is also known as the window layer, since it lets the light pass down to absorber layer 106.

In a typical thick-film solar cell, absorber layer 106 and window layer 108 can be made from the same semiconductor material but have different carrier types (dopants) and/or carrier concentrations in order to give the two layers their distinct p-type and n-type properties. In thin-film solar cells in which copper-indium-gallium-diselenide (CIGS) is the absorber layer 106, the use of CdS to form junction partner 108 has resulted in high efficiency cells. Other materials that can be used for junction partner 108 include, but are not limited to, In₂Se₃, In₂S₃, ZnS, ZnSe, CdInS, CdZnS, ZnIn₂Se₄, Zn₁₋ₓMgₓO, CdS, SnO₂, ZnO, ZrO₂ and doped ZnO.

Layer 110 is the counter electrode, which completes the functioning cell. Counter electrode 110 is used to draw current away from the junction since junction partner 108 is generally too resistive to serve this function. As such, counter electrode 110 should be highly conductive and transparent to light. Counter electrode 110 can in fact be a comb-like structure of metal printed onto layer 108 rather than forming a discrete layer. Counter electrode 110 is typically a transparent conductive oxide (TCO) such as doped zinc oxide (e.g., aluminum doped zinc oxide, gallium doped zinc oxide, boron dope zinc oxide), indium-tin-oxide (ITO), tin oxide (SnO₂), or indium-zinc oxide. However, even when a TCO layer is present, a bus bar network 114 is typically needed in conventional solar cells to draw off current since the TCO has too much resistance to efficiently perform this function in larger solar cells. Network 114 shortens the distance charge carriers must move in the TCO layer in order to reach the metal contact, thereby reducing resistive losses. The metal bus bars, also termed grid lines, can be made of any reasonably conductive metal such as, for example, silver, steel or aluminum. In the design of network 114, there is design a trade off between thicker grid lines that are more electrically conductive but block more light, and thin grid lines that are less electrically conductive but block less light. The metal bars are preferably configured in a comb-like arrangement to permit light rays through TCO layer 110. Bus bar network layer 114 and TCO layer 110, combined, act as a single metallurgical unit, functionally interfacing with a first ohmic contact to form a current collection circuit. In U.S. Pat. No. 6,548,751 to Sverdrup et al., hereby incorporated by reference herein in its entirety, a combined silver bus bar network and indium-tin-oxide layer function as a single, transparent ITO/Ag layer.

Layer 112 is an antireflective coating that can allow a significant amount of extra light into the cell. Depending on the intended use of the cell, it might be deposited directly on the top conductor as illustrated in FIG. 1. Alternatively or additionally, antireflective coating 112 made be deposited on a separate cover glass that overlays top electrode 110. Ideally, the antireflective coating reduces the reflection of the cell to very near zero over the spectral region in which photoelectric absorption occurs, and at the same time increases the reflection in the other spectral regions to reduce heating. U.S. Pat. No. 6,107,564 to Aguilera et al., hereby incorporated by reference herein in its entirety, describes representative antireflective coatings that are known in the art.

Solar cells typically produce only a small voltage. For example, silicon based solar cells produce a voltage of about 0.6 volts (V). Thus, solar cells are interconnected in series or parallel in order to achieve greater voltages. When connected in series, voltages of individual cells add together while current remains the same. Thus, solar cells arranged in series reduce the amount of current flow through such cells, compared to analogous solar cells arrange in parallel, thereby improving efficiency. As illustrated in FIG. 1, the arrangement of solar cells in series is accomplished using interconnects 116. In general, an interconnect 116 places the first electrode of one solar cell in electrical communication with the counter-electrode of an adjoining solar cell.

Many solar cell junctions are sensitive to moisture. Over time, moisture seeps into the solar cell and causes the solar cell junction to corrode. To prevent such moisture from getting into the solar cell, the solar cell is typically encapsulated by a glass panel. Thus, referring to FIG. 1, a glass panel may added either between top electrode 110 and antireflective coating 112 or above antireflective coating. Often, the glass panel is sealed onto the solar cell using a layer of silicone or EVA. Thus, between this glass panel and substrate 102 serve to protect the solar cell from moisture. The week point in such a design is the edges of the solar cell. An example of a solar cell edge is side 160 of the solar cell depicted in FIG. 1. In the art, these edges have been coated with organic polymers in order to prevent moisture from corroding the solar cell junction. However, while such organic polymers resist water, they are not impervious to water and, over time, water seeps into the solar cells causing corrosion of the solar cell. Thus, what is needed in the art are true waterproof seals for the edges of solar cells.

Discussion or citation of a reference herein will not be construed as an admission that such reference is prior art.

### 3. SUMMARY

One aspect provides a solar cell unit comprising one or more solar cells forming a solar cell unit. The solar cell unit has a first end and a second end and comprises a substrate that is, for example, tubular shaped or rigid solid rod shaped. Each solar cell in the one or more solar cells in the solar cell unit has a back-electrode disposed on the substrate, a semiconductor junction disposed on the back-electrode, and a transparent conductive disposed on the semiconductor junction. A transparent casing is disposed onto the solar cell unit. A first sealant cap that is hermetically sealed to the first end of the solar cell unit.

In some embodiments, the solar cell unit further comprises a second sealant cap that is hermetically sealed to the second end of the solar cell unit thereby rendering the solar cell unit waterproof. In some embodiments, the first sealant cap is made of metal, metal alloy, or glass. In some embodiments, the first sealant cap is hermetically sealed to an inner surface or an outer surface of the transparent casing. In some embodiments, the transparent casing is made of borosilicate glass and the first sealant cap is made of KOVAR. In some embodiments, the transparent casing is made of soda lime glass and the first sealant cap is made of a low expansion stainless steel alloy.

In some embodiments, the first sealant cap is made of aluminum, molybdenum, tungsten, vanadium, rhodium, niobium, chromium, tantalum, titanium, steel, nickel, platinum, silver, gold, an alloy thereof, or any combination thereof. In some embodiments, the first sealant cap is made of indium tin oxide, titanium nitride, tin oxide, fluorine doped tin oxide, doped zinc oxide, aluminum doped zinc oxide, gallium doped zinc oxide, boron dope zinc oxide, or indium-zinc oxide. In some embodiments, the first sealant cap is made of aluminosilicate glass, borosilicate glass, dichroic glass, germanium/semiconductor glass, glass ceramic, silicate/fused silica glass, soda lime glass, quartz glass, chalcogenide/sulphide glass, fluoride glass, pyrex glass, a glass-based phenolic, cereated glass, or flint glass.

In some embodiments, the first sealant cap is sealed to the solar cell unit with a continuous strip of sealant. The continuous strip of sealant can be, for example, on an inner edge of the first sealant cap, on an outer edge of the first sealant cap, on an outer edge of the transparent casing, or on an inner edge of the transparent casing. In some embodiments, the continuous strip of sealant is formed from glass frit, sol-gel, or ceramic cement.

In some embodiments, the first sealant cap is in electrical contact with the back-electrode and the first sealant cap serves as an electrode for the back-electrode. In some embodiments, the first sealant cap is in electrical contact with the transparent conductive layer and the first sealant cap serves as an electrode for the transparent conductive layer.

In some embodiments, the solar cell unit further comprises a second sealant cap that is hermetically sealed to the second end of the solar cell unit, thereby rendering the solar cell unit waterproof. In some such embodiments, the first sealant cap and the second sealant cap are each made of an electrically conducting metal. In some embodiments, the first sealant cap is in electrical contact with the back-electrode and the first sealant cap serves as an electrode for the back-electrode. Further, in some embodiments, the second sealant cap is in electrical contact with the transparent conductive layer and the second sealant cap serves as an electrode for the transparent conductive layer.

One aspect provides an elongated solar cell unit comprising a substrate, one or more solar cells disposed on the substrate, a transparent casing disposed onto the one or more solar cells, the transparent nonplanar casing having a first end and a second end, and a first sealant cap that is hermetically sealed to the first end of the transparent nonplanar casing. The one or more solar cells can be unifacial, bifacial, or omnifacial.

Another aspect provides a solar cell unit comprising (i) a substrate, (ii) one or more bifacial or omnifacial solar cells disposed on the substrate, (iii) a transparent casing disposed onto the one or more bifacial or omnifacial solar cells, the transparent nonplanar casing having a first end and a second end and, a first sealant cap that is hermetically sealed to the first end of the transparent nonplanar casing. As used herein an “omnifacial” object has a single surface around the perimeter of a cross-section the object. Cylindrical objects are an example of an omnifacial object. Hollow objects (e.g., hollow tubes) are also considered to be omnifacial because the exterior surface, is omnifacial. The solar cells can be “multifacial,” e.g., bifacial, trifacial, or having more than three faces. A multifacial object (e.g., solar cell) has a plurality of faces that each face in different directions. An example of a bifacial solar cell is one having two opposing surfaces. In a multifacial configuration, the shape of the cross section of the solar cell can be described by any combination of straight lines and curved features. Some examples of multifacial solar cells are provided below. A “unifacial” solar cell is one having only a single face that faces a single direction.

### 4. BRIEF DESCRIPTION OF THE DRAWINGS

FIG. 1 illustrates interconnected solar cells in accordance with the prior art.

FIG. 2A illustrates a photovoltaic element with tubular casing, in accordance with an embodiment.

FIG. 2B illustrates a cross-sectional view of an elongated solar cell in a transparent tubular casing, in accordance with an embodiment.

FIGS. 3A-3K illustrate processing steps for forming a monolithically integrated solar cell unit in accordance with an embodiment.

FIG. 3L illustrates the disposing of an optional filler layer onto a solar cell unit in accordance with an embodiment.

FIG. 3M illustrates the placement of transparent tubular casing onto a solar cell unit in accordance with an embodiment.

FIGS. 3N-3O illustrate a sealant cap that forms a waterproof seal with the outer edge of the transparent tubular casing of a solar cell unit in accordance with an embodiment.

FIGS. 3P-3Q illustrate a sealant cap that forms a waterproof seal with the inner edge of the transparent tubular casing of a solar cell unit in accordance with an embodiment.

FIGS. 3R-3S illustrate a sealant cap that forms a waterproof seal with portions of the inner edge and portions of the outer edge of the transparent tubular casing of a solar cell unit in accordance with an embodiment.

FIGS. 3T-3U illustrate a sealant cap that forms a waterproof seal with the outer edge of the substrate and the inner edge of the transparent tubular casing of a solar cell unit in accordance with an embodiment.

FIGS. 4A-4D illustrate exemplary semiconductor junctions.

FIGS. 5A-B5 illustrate the used of sealant caps as electrode in accordance with an embodiment.

FIG. 6 illustrates an alternate shape for a sealant cap in accordance with an embodiment.

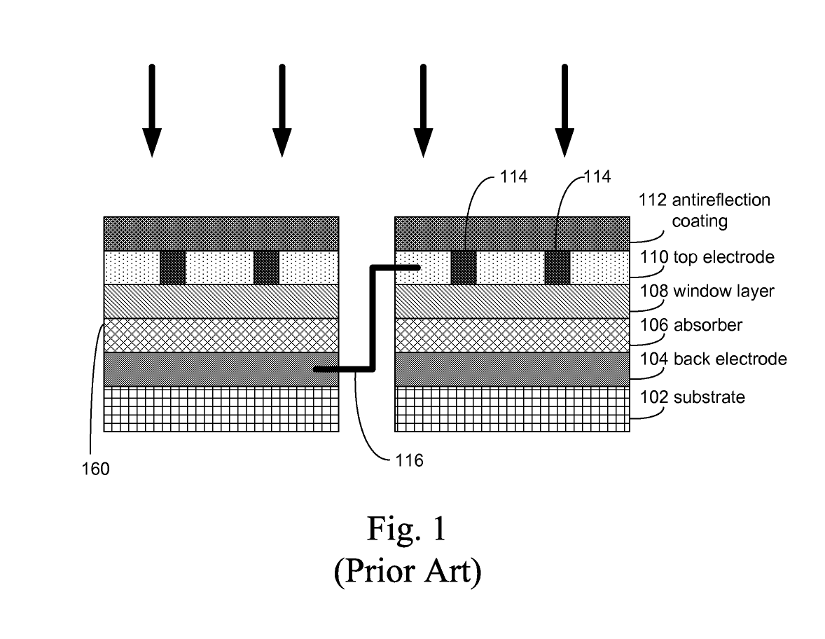

Like reference numerals refer to corresponding parts throughout the several views of the drawings. Dimensions are not drawn to scale.

### 5. DETAILED DESCRIPTION

Disclosed herein are solar cell units for converting solar energy into electrical energy and more particularly to improved waterproof solar cell units comprising one or more solar cells. The solar cell units are elongated.

### 5.1 Basic Structure

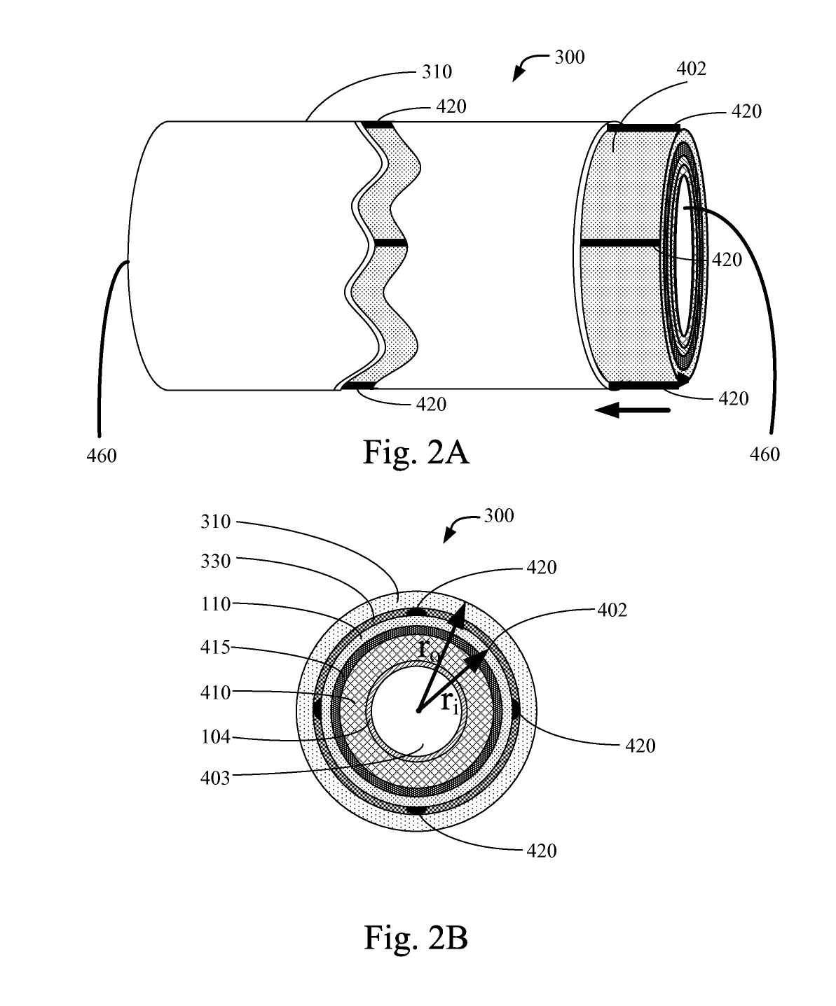

Individually covered elongated solar cell units 300 that are illustrated in the exemplary perspective view in FIG. 2A and cross-sectional view in FIG. 2B. In a solar cell unit 300, an one or more solar cell 402 are covered by a transparent casing 310. Solar cell unit 300 comprises one or more solar cells 402 coated with a transparent nonplanar casing 310.

In some embodiments, all or a portion of a solar cell unit 300 is rigid cylindrical, solid rod shaped, and/or characterized by a cross-section bounded by any one of a number of shapes other than the circular shaped depicted in FIG. 2. The cross-sectional bounding shape can be, for example, any one of circular, ovoid, or any shape characterized by one or more smooth curved surfaces, or any splice of smooth curved surfaces. The cross-sectional bounding shape can be an n-gon, where n is 3, 4, 5, or greater than 5. The cross-sectional bounding shape can also be linear in nature, including triangular, pentangular, hexagonal, or having any number of linear segmented surfaces. Or, the cross-section can be bounded by any combination of linear surfaces, arcuate surfaces, or curved surfaces. As described herein, for ease of discussion only, an omnifacial cross-section is illustrated to represent nonplanar embodiments of solar cell unit 300. In some embodiments, solar cell unit 300 is cylindrical or approximately cylindrical shape. In some embodiments, solar cell unit 300 is characterized by an irregular cross-section so long as the solar cell unit 300, taken as a whole, is roughly cylindrical. Such cylindrical shapes can be solid (e.g., a rod) or hollowed (e.g., a tube).

In some embodiments, an elongated solar cell unit 300 has at least one width dimension and a longitudinal dimension. In some embodiments, the longitudinal dimension of the solar cell unit 300 is at least four times greater than a width dimension of the solar cell unit 300. In other embodiments, the longitudinal dimension of the elongated solar cell unit 300 is at least five times greater than a width dimension of the elongated solar cell unit 300. In yet other embodiments, the longitudinal dimension of the elongated solar cell unit 300 is at least six times greater than a width dimension of the elongated solar cell unit 300. In some embodiments, the longitudinal dimension of the elongated solar cell unit 300 is 10 cm or greater. In other embodiments, the longitudinal dimension of the elongated solar cell unit 300 is 50 cm or greater. In some embodiments, a width dimension of the elongated solar cell unit 300 is 1 cm or greater. In other embodiments, a width dimension of the elongated solar cell unit 300 is 5 cm or greater. In yet other embodiments, a width dimension of the elongated solar cell unit 300 is 10 cm or greater.

In some embodiments, a first portion of the elongated solar cell unit 300 is characterized by a first cross-sectional shape and a second portion of the elongated solar cell unit 300 is characterized by a second cross-sectional shape, where the first and second cross-sectional shapes are the same or different. In some embodiments, at least ten percent, at least twenty percent, at least thirty percent, at least forty percent, at least fifty percent, at least sixty percent, at least seventy percent, at least eighty percent, at least ninety percent, or all of the length of the elongated solar cell unit 300 is characterized by the first cross-sectional shape and the remainder of the elongated solar cell unit 300 is characterized by one or more cross-sectional shapes other than the first cross-sectional shape. In some embodiments, the first cross-sectional shape is planar (e.g., has no arcuate side) and the second cross-sectional shape has at least one arcuate side.

Although solar cell units 300 are described in the context of either the encapsulated embodiments or covered (e.g., circumferentially covered) embodiments, any transparent nonplanar casing that provides support and protection to solar cells 402 can be used.

Substrate 403. The substrate 403 serves as a substrate for a solar cell 402. In some embodiments, the substrate 403 is made of a plastic, metal, metal alloy, or glass. In some embodiments, the substrate 403 is nonplanar. In some embodiments, the substrate 403 has a hollow core, as illustrated in FIG. 2B. In some embodiments, the substrate 403 has a solid core. In some embodiments, the substrate 403 is cylindrical or only approximately cylindrical, meaning that a cross-section taken at a right angle to the long axis of the substrate 403 defines a bounded structure other than a circle. As the term is used herein, such approximately shaped objects are still considered cylindrically.

In some embodiments, the substrate 403 is a solid cylindrical shape made out of, for example, a plastic, glass, metal, or metal alloy. In some embodiments, the substrate 403 is optically transparent in wavelengths that are generally used by the solar cell to generate electricity. In some embodiments, the substrate 403 is not optically transparent.

In some embodiments, all or a portion of the substrate 403 is rigid cylindrical, solid rod shaped, and/or characterized by a cross-section bounded by any one of a number of shapes other than the circular shaped depicted in FIG. 2. The cross-sectional bounding shape can be, for example, any one of circular, ovoid, or any shape characterized by one or more smooth curved surfaces, or any splice of smooth curved surfaces. The cross-sectional bounding shape can be an n-gon, where n is 3, 5, or greater than 5. The cross-sectional bounding shape can also be linear in nature, including triangular, rectangular, pentangular, hexagonal, or having any number of linear segmented surfaces. Or, the cross-section can be bounded by any combination of linear surfaces, arcuate surfaces, or curved surfaces. As described herein, for ease of presentation only, an omnifacial cross-section is illustrated to represent nonplanar the substrate 403. In some embodiments, a substrate 403 is cylindrical or approximately cylindrical shape. In some embodiments, a substrate 403 is characterized by an irregular cross-section so long as the substrate, taken as a whole, is roughly cylindrical. Such cylindrical shapes can be solid (e.g., a rod) or hollowed (e.g., a tube).

In some embodiments, a first portion of the substrate 403 is characterized by a first cross-sectional shape and a second portion of the substrate 403 is characterized by a second cross-sectional shape, where the first and second cross-sectional shapes are the same or different. In some embodiments, at least ten percent, at least twenty percent, at least thirty percent, at least forty percent, at least fifty percent, at least sixty percent, at least seventy percent, at least eighty percent, at least ninety percent, or all of the length of the substrate 403 is characterized by the first cross-sectional shape and the remainder of the substrate is characterized by one or more cross-sectional shapes other than the first cross-sectional shape. In some embodiments, the first cross-sectional shape is planar (e.g., has no arcuate side) and the second cross-sectional shape has at least one arcuate side.

In some embodiments, the substrate 403 is made of a urethane polymer, an acrylic polymer, a fluoropolymer, polybenzamidazole, polyimide, polytetrafluoroethylene, polyetheretherketone, polyamide-imide, glass-based phenolic, polystyrene, cross-linked polystyrene, polyester, polycarbonate, polyethylene, polyethylene, acrylonitrile-butadiene-styrene, polytetrafluoro-ethylene, polymethacrylate, nylon 6,6, cellulose acetate butyrate, cellulose acetate, rigid vinyl, plasticized vinyl, or polypropylene. In some embodiments, substrate 403 is made of aluminosilicate glass, borosilicate glass (e.g., Pyrex, Duran, Simax, etc.), dichroic glass, germanium/semiconductor glass, glass ceramic, silicate/fused silica glass, soda lime glass, quartz glass, chalcogenide/sulphide glass, fluoride glass, pyrex glass, a glass-based phenolic, cereated glass, or flint glass.

In some embodiments, the substrate 403 is made of a material such as polybenzamidazole (e.g., CELAZOLE®, available from Boedeker Plastics, Inc., Shiner, Tex.). In some embodiments, the substrate 102 is made of polymide (e.g., DuPont™ VESPEL®, or DUPONT® KAPTON®, Wilmington, Del.). In some embodiments, the substrate 403 is made of polytetrafluoroethylene (PTFE) or polyetheretherketone (PEEK), each of which is available from Boedeker Plastics, Inc. In some embodiments, the substrate 403 is made of polyamide-imide (e.g., TORLON® PAI, Solvay Advanced Polymers, Alpharetta, Ga.).

In some embodiments, the substrate 403 is made of a glass-based phenolic. Phenolic laminates are made by applying heat and pressure to layers of paper, canvas, linen or glass cloth impregnated with synthetic thermosetting resins. When heat and pressure are applied to the layers, a chemical reaction (polymerization) transforms the separate layers into a single laminated material with a “set” shape that cannot be softened again. Therefore, these materials are called “thermosets.” In some embodiments, the substrate 403 is a phenoloic laminate having a NEMA grade of G-3, G-5, G-7, G-9, G-10 or G-11. Exemplary phenolic laminates are available from Boedeker Plastics, Inc.

In some embodiments, the substrate 403 is made of polystyrene. Examples of polystyrene include general purpose polystyrene and high impact polystyrene as detailed in Marks' Standard Handbook for Mechanical Engineers, ninth edition, 1987, McGraw-Hill, Inc., p. 6-174, which is hereby incorporated by reference herein in its entirety. In still other embodiments, the substrate 403 is made of cross-linked polystyrene. One example of cross-linked polystyrene is REXOLITE® (available from San Diego Plastics Inc., National City, Calif.). REXOLITE® is a thermoset, in particular a rigid and translucent plastic produced by cross linking polystyrene with divinylbenzene.

In still other embodiments, the substrate 403 is made of polycarbonate. Such polycarbonates can have varying amounts of glass fibers (e.g., 10%, 20%, 30%, or 40%) in order to adjust tensile strength, stiffness, compressive strength, as well as the thermal expansion coefficient of the material. Exemplary polycarbonates are ZELUX® M and ZELUX® W, which are available from Boedeker Plastics, Inc.

In some embodiments, the substrate 403 is made of polyethylene. In some embodiments, the substrate 403 is made of low density polyethylene (LDPE), high density polyethylene (HDPE), or ultra high molecular weight polyethylene (UHMW PE). Chemical properties of HDPE are described in Marks' Standard Handbook for Mechanical Engineers, ninth edition, 1987, McGraw-Hill, Inc., p. 6-173. In some embodiments, the substrate 403 is made of acrylonitrile-butadiene-styrene, polytetrifluoro-ethylene (Teflon), polymethacrylate (lucite or plexiglass), nylon 6,6, cellulose acetate butyrate, cellulose acetate, rigid vinyl, plasticized vinyl, or polypropylene. Chemical properties of these materials are described in Marks' Standard Handbook for Mechanical Engineers, ninth edition, 1987, McGraw-Hill, Inc., pp. 6-172 through 6-175.

Additional exemplary materials that can be used to form the substrate 102 are found in Modern Plastics Encyclopedia, McGraw-Hill; Reinhold Plastics Applications Series, Reinhold Roff, Fibres, Plastics and Rubbers, Butterworth; Lee and Neville, Epoxy Resins, McGraw-Hill; Bilmetyer, Textbook of Polymer Science, Interscience; Schmidt and Marlies, Principles of high polymer theory and practice, McGraw-Hill; Beadle (ed.), Plastics, Morgan-Grampiand, Ltd., 2 vols. 1970; Tobolsky and Mark (eds.), Polymer Science and Materials, Wiley, 1971; Glanville, The Plastics's Engineer's Data Book, Industrial Press, 1971; Mohr (editor and senior author), Oleesky, Shook, and Meyers, SPI Handbook of Technology and Engineering of Reinforced Plastics Composites, Van Nostrand Reinhold, 1973, each of which is hereby incorporated by reference herein in its entirety.

In some embodiments, a cross-section of the substrate 403 is circumferential and has an outer diameter of between 3 mm and 100 mm, between 4 mm and 75 mm, between 5 mm and 50 mm, between 10 mm and 40 mm, or between 14 mm and 17 mm. In some embodiments, a cross-section of the substrate 403 is circumferential and has an outer diameter of between 1 mm and 1000 mm.

In some embodiments, the substrate 403 is a tube with a hollowed inner portion. In such embodiments, a cross-section of the substrate 403 is characterized by an inner radius defining the hollowed interior and an outer radius. The difference between the inner radius and the outer radius is the thickness of the substrate 403. In some embodiments, the thickness of the substrate 102 is between 0.1 mm and 20 mm, between 0.3 mm and 10 mm, between 0.5 mm and 5 mm, or between 1 mm and 2 mm. In some embodiments, the inner radius is between 1 mm and 100 mm, between 3 mm and 50 mm, or between 5 mm and 10 mm.

In some embodiments, the substrate 403 has a length (perpendicular to the plane defined by FIG. 2B) that is between 5 mm and 10,000 mm, between 50 mm and 5,000 mm, between 100 mm and 3000 mm, or between 500 mm and 1500 mm. In one embodiment, the substrate 403 is a hollowed tube having an outer diameter of 15 mm and a thickness of 1.2 mm, and a length of 1040 mm. Although the substrate 403 is shown as solid in FIG. 2, it will be appreciated that in many embodiments, the substrate 403 will have a hollow core and will adopt a rigid tubular structure such as that formed by a glass tube.

In some embodiments, the substrate 403, and hence, the solar cell unit 300, is rigid. Rigidity of a material can be measured using several different metrics including, but not limited to, Young's modulus. In solid mechanics, Young's Modulus (E) (also known as the Young Modulus, modulus of elasticity, elastic modulus or tensile modulus) is a measure of the stiffness of a given material. It is defined as the ratio, for small strains, of the rate of change of stress with strain. This can be experimentally determined from the slope of a stress-strain curve created during tensile tests conducted on a sample of the material. Young's modulus for various materials is given in the following table.

| | Young's modulus | Young's modulus (E) in |
|---|---|---|
| Material | (E) in GPa | lbf/in² (psi) |
| Rubber (small strain) | 0.01-0.1 | 1,500-15,000 |
| Low density | 0.2 | 30,000 |
| polyethylene | | |
| Polypropylene | 1.5-2 | 217,000-290,000 |
| Polyethylene | 2-2.5 | 290,000-360,000 |
| terephthalate | | |
| Polystyrene | 3-3.5 | 435,000-505,000 |
| Nylon | 3-7 | 290,000-580,000 |
| Aluminum alloy | 69 | 10,000,000 |
| Glass (all types) | 72 | 10,400,000 |
| Brass and bronze | 103-124 | 17,000,000 |
| Titanium (Ti) | 105-120 | 15,000,000-17,500,000 |
| Carbon fiber reinforced | 150 | 21,800,000 |
| plastic (unidirectional, | | |
| along grain) | | |
| Wrought iron and steel | 190-210 | 30,000,000 |
| Tungsten (W) | 400-410 | 58,000,000-59,500,000 |
| Silicon carbide (SiC) | 450 | 65,000,000 |
| Tungsten carbide (WC) | 450-650 | 65,000,000-94,000,000 |
| Single Carbon nanotube | 1,000+ | 145,000,000 |
| Diamond (C) | 1,050-1,200 | 150,000,000-175,000,000 |

In some embodiments of the present application, a material (e.g., a substrate 403) is deemed to be rigid when it is made of a material that has a Young's modulus of 20 GPa or greater, 30 GPa or greater, 40 GPa or greater, 50 GPa or greater, 60 GPa or greater, or 70 GPa or greater. In some embodiments of the present application a material (e.g., the substrate 403) is deemed to be rigid when the Young's modulus for the material is a constant over a range of strains. Such materials are called linear, and are said to obey Hooke's law. Thus, in some embodiments, the substrate 403 is made out of a linear material that obeys Hooke's law. Examples of linear materials include, but are not limited to, steel, carbon fiber, and glass. Rubber and soil (except at very low strains) are non-linear materials.

Back-electrode 104. A back-electrode 104 is disposed on substrate 403. The back-electrode 104 serves as one electrode in the assembly. In general, the back-electrode 104 is made out of any material such that can support the photovoltaic current generated by the solar cell unit 300 with negligible resistive losses.

In some embodiments, the back-electrode 104 is composed of any conductive material, such as aluminum, molybdenum, tungsten, vanadium, rhodium, niobium, chromium, tantalum, titanium, steel, nickel, platinum, silver, gold, an alloy thereof (e.g. Kovar), or any combination thereof. In some embodiments, the back-electrode 104 is composed of any conductive material, such as indium tin oxide, titanium nitride, tin oxide, fluorine doped tin oxide, doped zinc oxide, aluminum doped zinc oxide, gallium doped zinc oxide, boron dope zinc oxide indium-zinc oxide, a metal-carbon black-filled oxide, a graphite-carbon black-filled oxide, a carbon black-carbon black-filled oxide, a superconductive carbon black-filled oxide, an epoxy, a conductive glass, or a conductive plastic. A conductive plastic is one that, through compounding techniques, contains conductive fillers which, in turn, impart their conductive properties to the plastic. In some embodiments, a conductive plastic is used to form the back-electrode 104 and the conductive plastic contains fillers that form sufficient conductive current-carrying paths through the plastic matrix to support the photovoltaic current generated by the solar cell unit 300 with negligible resistive losses. The plastic matrix of the conductive plastic is typically insulating, but the composite produced exhibits the conductive properties of the filler.

Semiconductor junction 410. A semiconductor junction 410 is formed on the back-electrode 104. Semiconductor junction 410 is, for example, any photovoltaic homojunction, heterojunction, heteroface junction, buried homojunction, p-i-n junction or a tandem junction having an absorber layer that is a direct band-gap absorber (e.g., crystalline silicon) or an indirect band-gap absorber (e.g., amorphous silicon). Such junctions are described in Chapter 1 of Bube, Photovoltaic Materials, 1998, Imperial College Press, London, as well as Lugue and Hegedus, 2003, Handbook of Photovoltaic Science and Engineering, John Wiley & Sons, Ltd., West Sussex, England, each of which is hereby incorporated by reference herein in its entirety. Details of exemplary types of semiconductors junctions 410 are disclosed in Section 5.2, below. Additionally, the junctions 410 can be multijunctions in which light traverses into the core of the junction 410 through multiple junctions that, preferably, have successfully smaller band gaps. In some embodiments, the semiconductor junction 410 includes a copper-indium-gallium-diselenide (CIGS) absorber layer.

Optional intrinsic layer 415. Optionally, there is a thin intrinsic layer (i-layer) 415 on the semiconductor junction 410. The i-layer 415 can be formed using any undoped transparent oxide including, but not limited to, zinc oxide, metal oxide, or any transparent material that is highly insulating. In some embodiments, the i-layer 415 is highly pure zinc oxide.

Transparent conductive layer 110. The transparent conductive layer 110 is disposed on the semiconductor junction 410 thereby completing the circuit. As noted above, in some embodiments, a thin i-layer 415 is disposed on semiconductor junction 410. In such embodiments, transparent conductive layer 110 is disposed on i-layer 415. In some embodiments, the transparent conductive layer 110 is made of tin oxide SnOₓ (with or without fluorine doping), indium-tin oxide (ITO), doped zinc oxide (e.g., aluminum doped zinc oxide, gallium doped zinc oxide, boron dope zinc oxide), indium-zinc oxide or any combination thereof. In some embodiments, the transparent conductive layer 110 is either p-doped or n-doped. In some embodiments, the transparent conductive layer 110 is made of carbon nanotubes. Carbon nanotubes are commercially available, for example, from Eikos (Franklin, Mass.) and are described in U.S. Pat. No. 6,988,925, which is hereby incorporated by reference herein in its entirety. For example, in embodiments where the outer semiconductor layer of the junction 410 is p-doped, transparent conductive layer 110 can be p-doped. Likewise, in embodiments where the outer semiconductor layer of the junction 410 is n-doped, the transparent conductive layer 110 can be n-doped. In general, the transparent conductive layer 110 is preferably made of a material that has very low resistance, suitable optical transmission properties (e.g., greater than 90%), and a deposition temperature that will not damage underlying layers of the semiconductor junction 410 and/or optional i-layer 415. In some embodiments, the transparent conductive layer 110 is an electrically conductive polymer material such as a conductive polytiophene, a conductive polyaniline, a conductive polypyrrole, a PSS-doped PEDOT (e.g., Bayrton), or a derivative of any of the foregoing. In some embodiments, the transparent conductive layer 110 comprises more than one layer, including a first layer comprising tin oxide SnOₓ (with or without fluorine doping), indium-tin oxide (ITO), indium-zinc oxide, doped zinc oxide (e.g., aluminum doped zinc oxide, gallium doped zinc oxide, boron dope zinc oxide) or a combination thereof and a second layer comprising a conductive polytiophene, a conductive polyaniline, a conductive polypyrrole, a PSS-doped PEDOT (e.g., Bayrton), or a derivative of any of the foregoing. Additional suitable materials that can be used to form transparent conductive layer are disclosed in United States Patent publication 2004/0187917A1 to Pichler, which is hereby incorporated by reference herein in its entirety.

Optional electrode strips 420. In some embodiments, counter-electrode strips or leads 420 are disposed on transparent conductive layer 110 in order to facilitate electrical current flow. In some embodiments, the electrode strips 420 are thin strips of electrically conducting material that run lengthwise along the long axis (cylindrical axis) of the cylindrically shaped solar cell, as depicted in FIG. 2A. In some embodiments, optional electrode strips are positioned at spaced intervals on the surface of the transparent conductive layer 110. For instance, in FIG. 2B, the electrode strips 420 run parallel to each other and are spaced out at ninety degree intervals along the cylindrical axis of the solar cell. In some embodiments, the electrode strips 420 are spaced out at five degree, ten degree, fifteen degree, twenty degree, thirty degree, forty degree, fifty degree, sixty degree, ninety degree or 180 degree intervals on the surface of transparent conductive layer 110. In some embodiments, there is a single electrode strip 420 on the surface of the transparent conductive layer 110. In some embodiments, there is no electrode strip 420 on the surface of transparent conductive layer 110. In some embodiments, there are two, three, four, five, six, seven, eight, nine, ten, eleven, twelve, fifteen or more, or thirty or more electrode strips on the transparent conductive layer 110, all running parallel, or near parallel, to each down the long (cylindrical) axis of the solar cell. In some embodiments the electrode strips 420 are evenly spaced about the perimeter of the transparent conductive layer 110, for example, as depicted in FIG. 2B. In alternative embodiments, the electrode strips 420 are not evenly spaced about the perimeter of transparent conductive layer 110. In some embodiments, the electrode strips 420 are only on one face of the solar cell. Elements 403, 104, 410, 415 (optional), and 110 of FIG. 2B collectively comprise solar cell 402 of FIG. 2A. In some embodiments, the electrode strips 420 are made of conductive epoxy, conductive ink, copper or an alloy thereof, aluminum or an alloy thereof, nickel or an alloy thereof, silver or an alloy thereof, gold or an alloy thereof, conductive glue, or a conductive plastic.

In some embodiments, there are electrode strips that run along the long (cylindrical) axis of the solar cell and these electrode strips are interconnected to each other by grid lines. These grid lines can be thicker than, thinner than, or the same width as the electrode strips. These grid lines can be made of the same or different electrically material as the electrode strips.

In some embodiments, the electrode strips 420 are deposited on transparent conductive layer 110 using ink jet printing. Examples of conductive ink that can be used for such strips include but are not limited to silver loaded or nickel loaded conductive ink. In some embodiments epoxies as well as anisotropic conductive adhesives can be used to construct electrode strips 420. In typical embodiments, such inks or epoxies are thermally cured in order to form electrode strips 420.

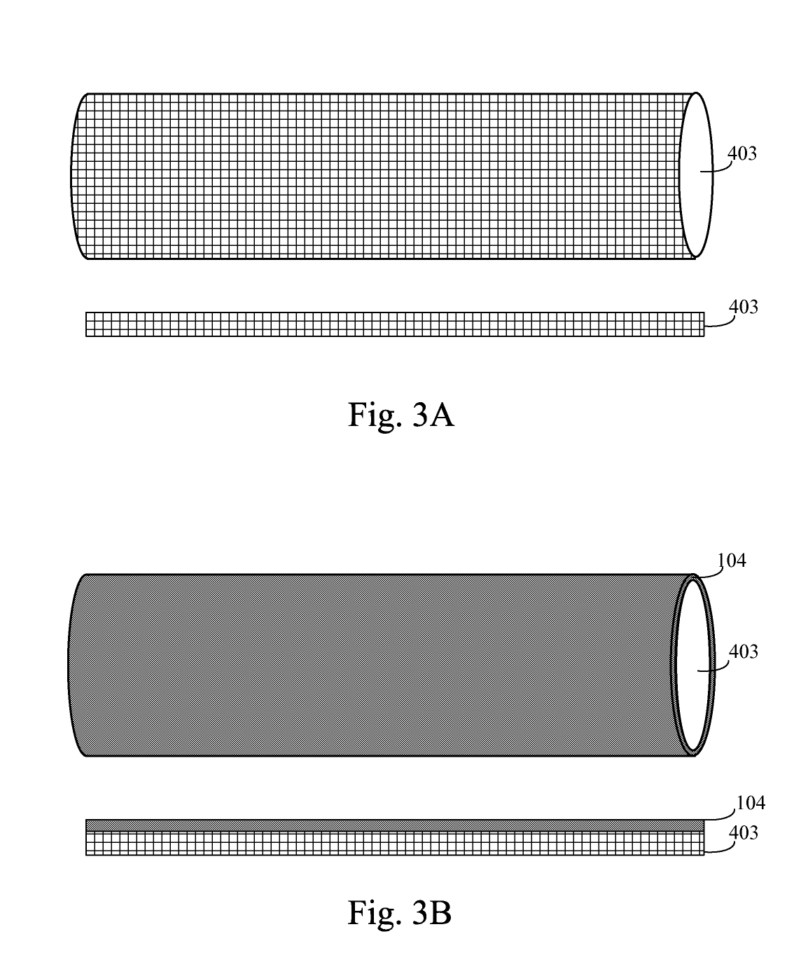

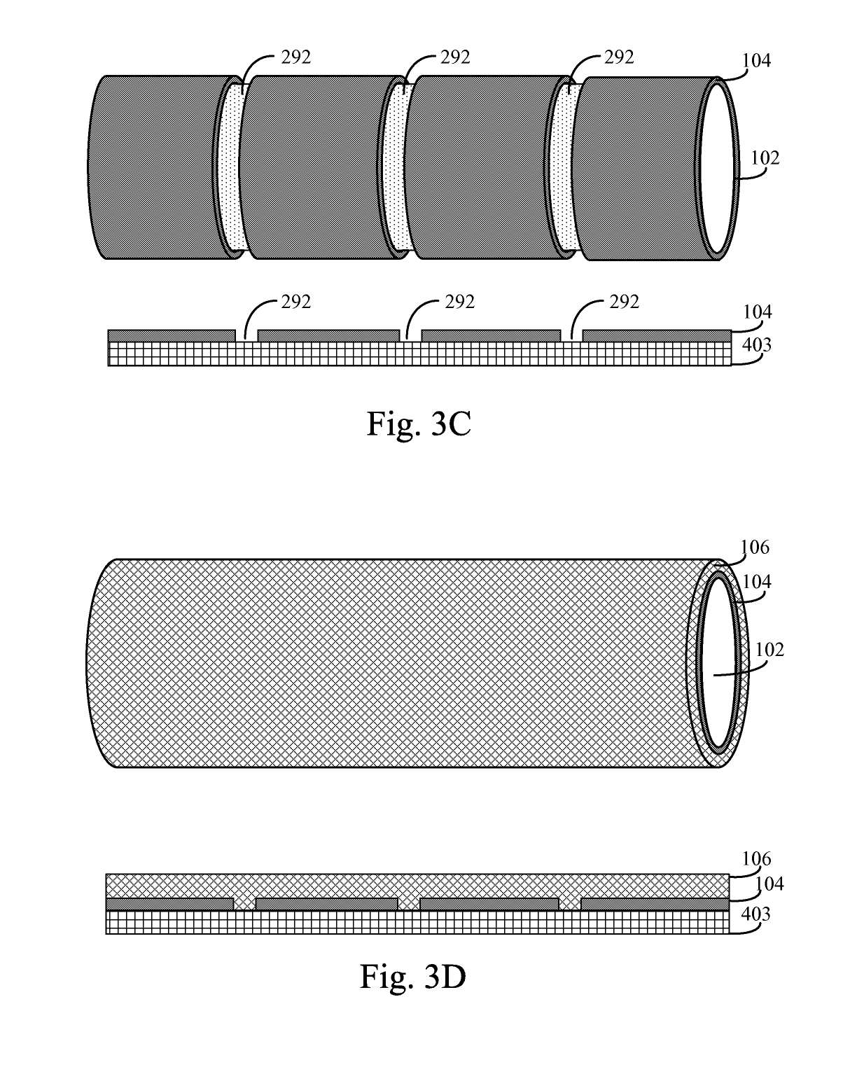

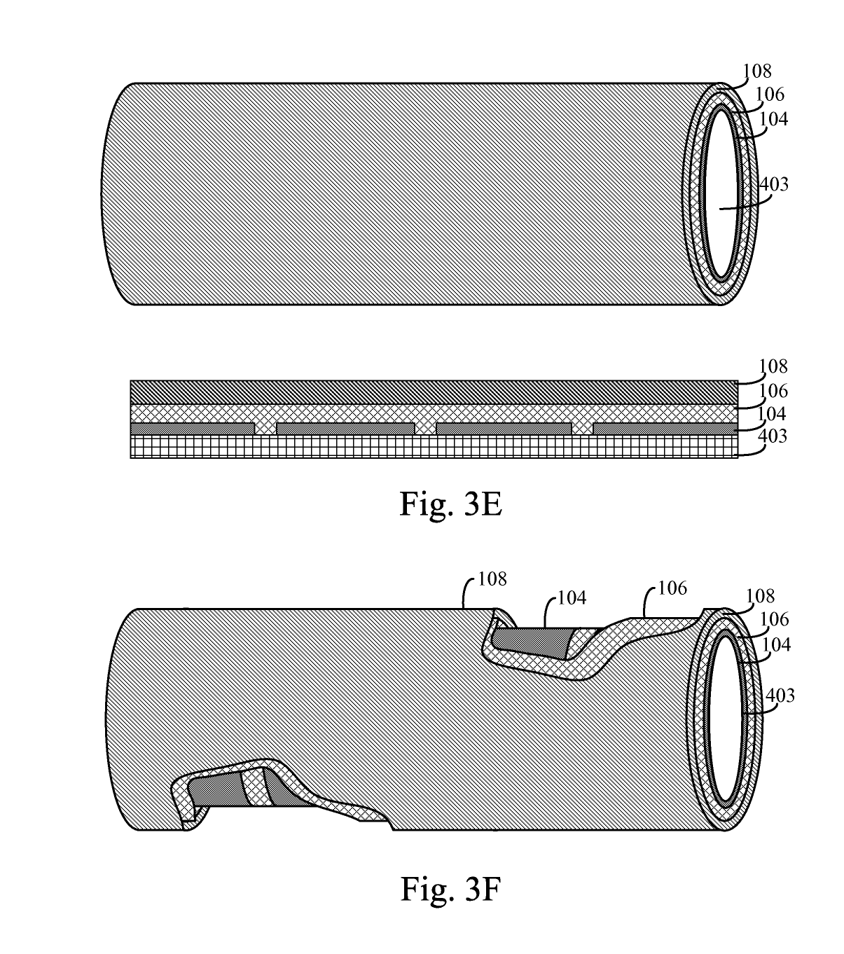

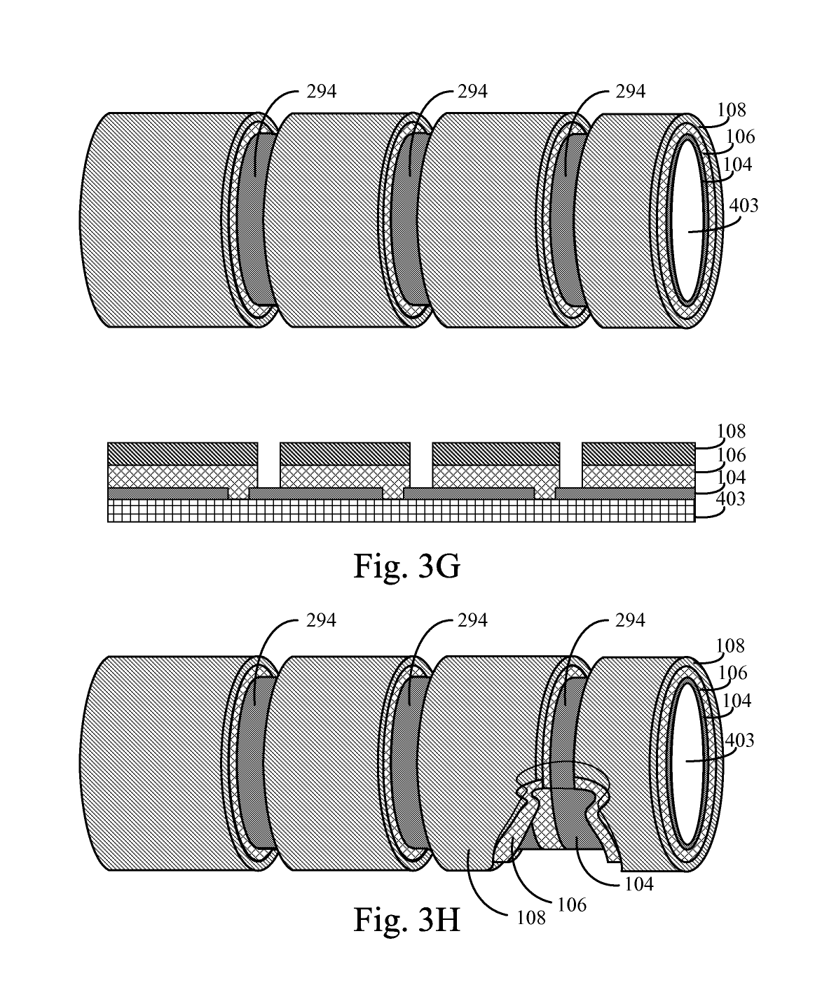

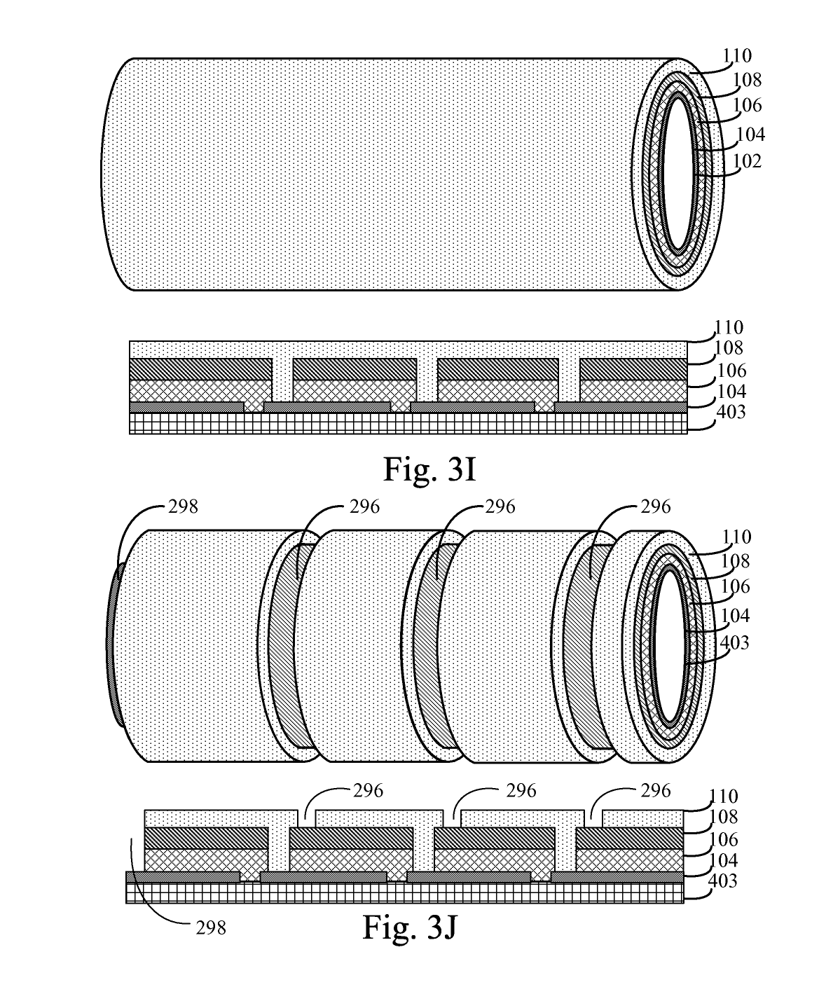

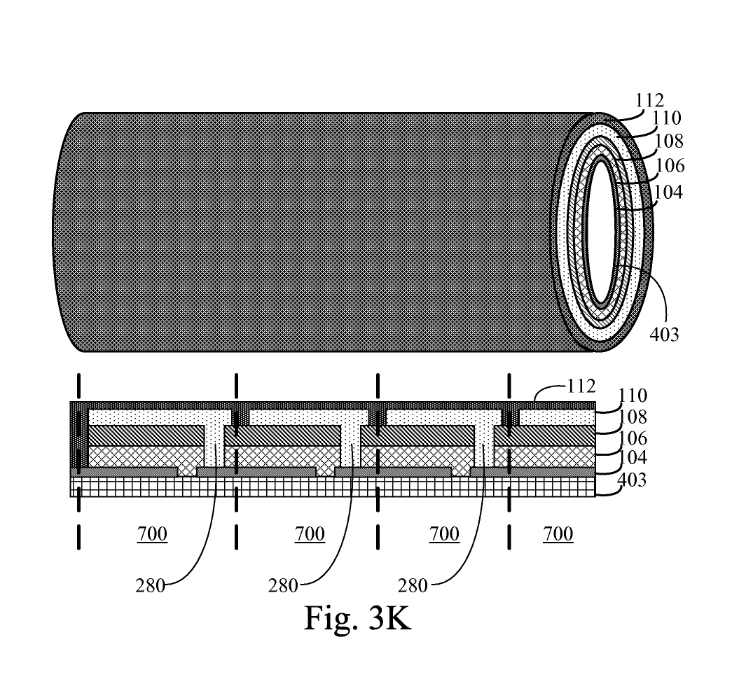

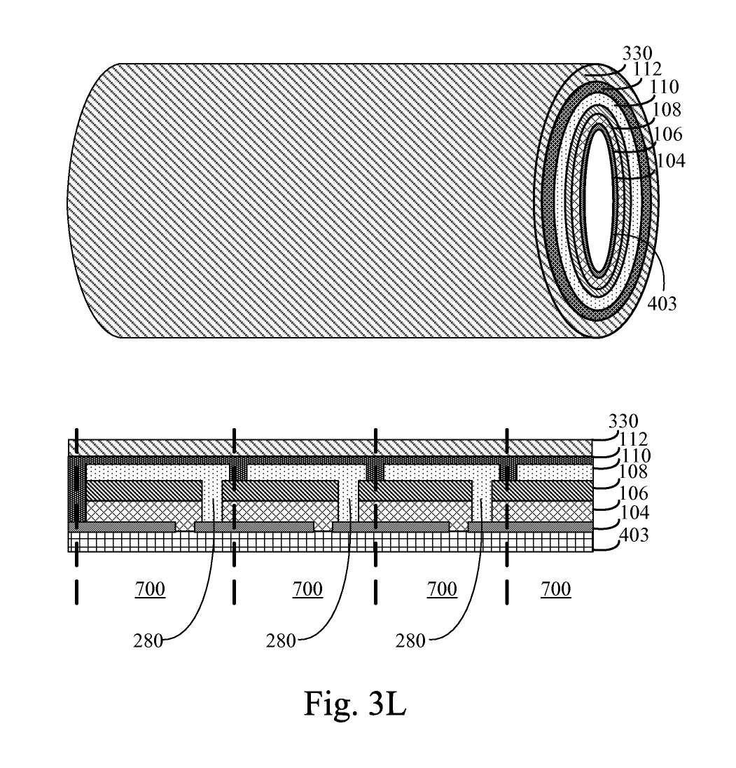

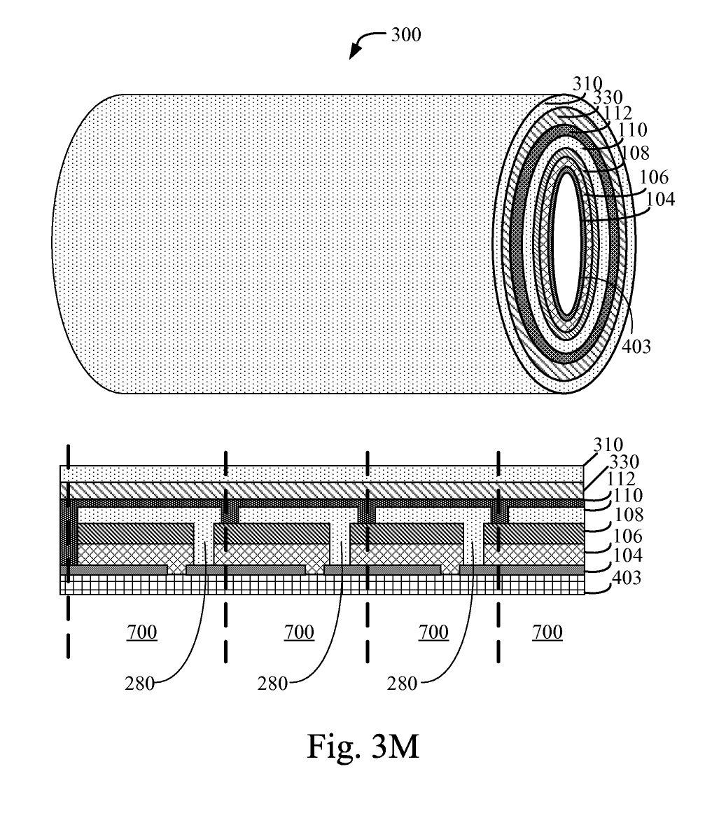

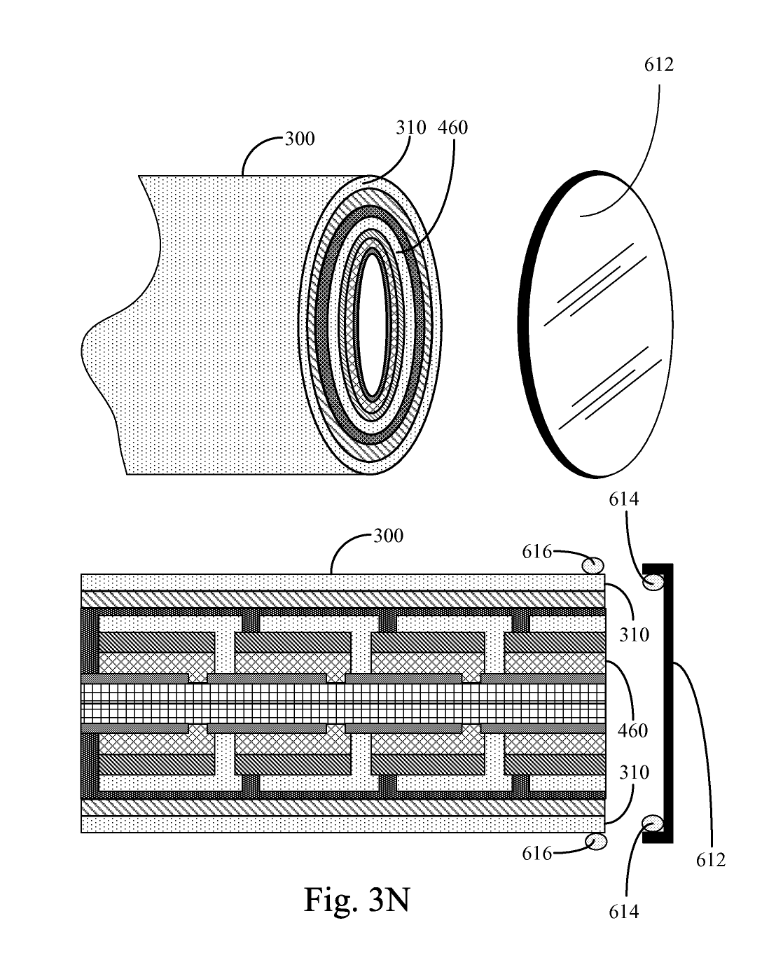

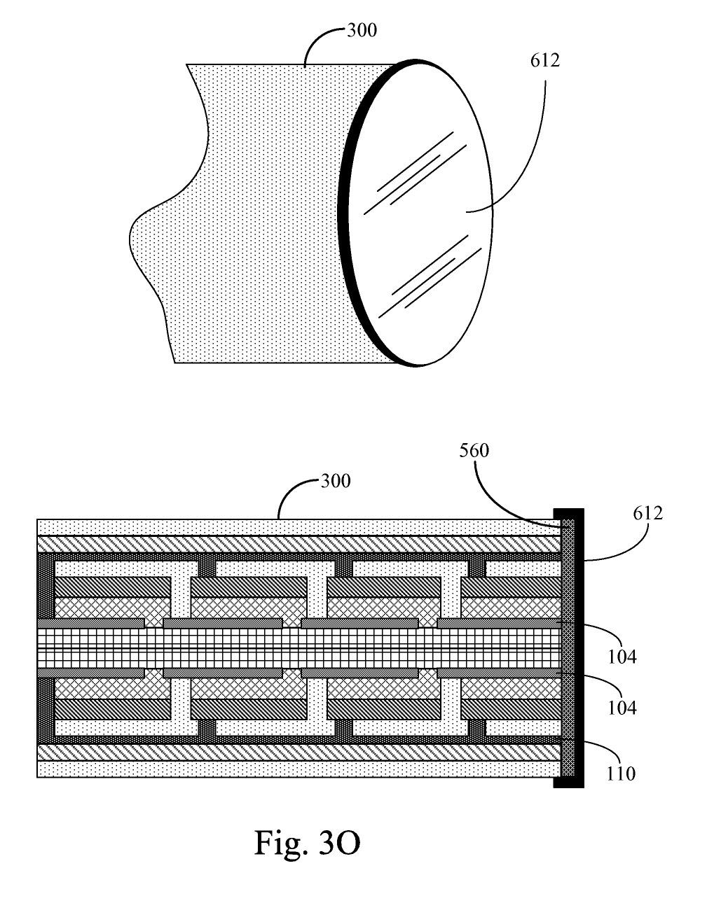

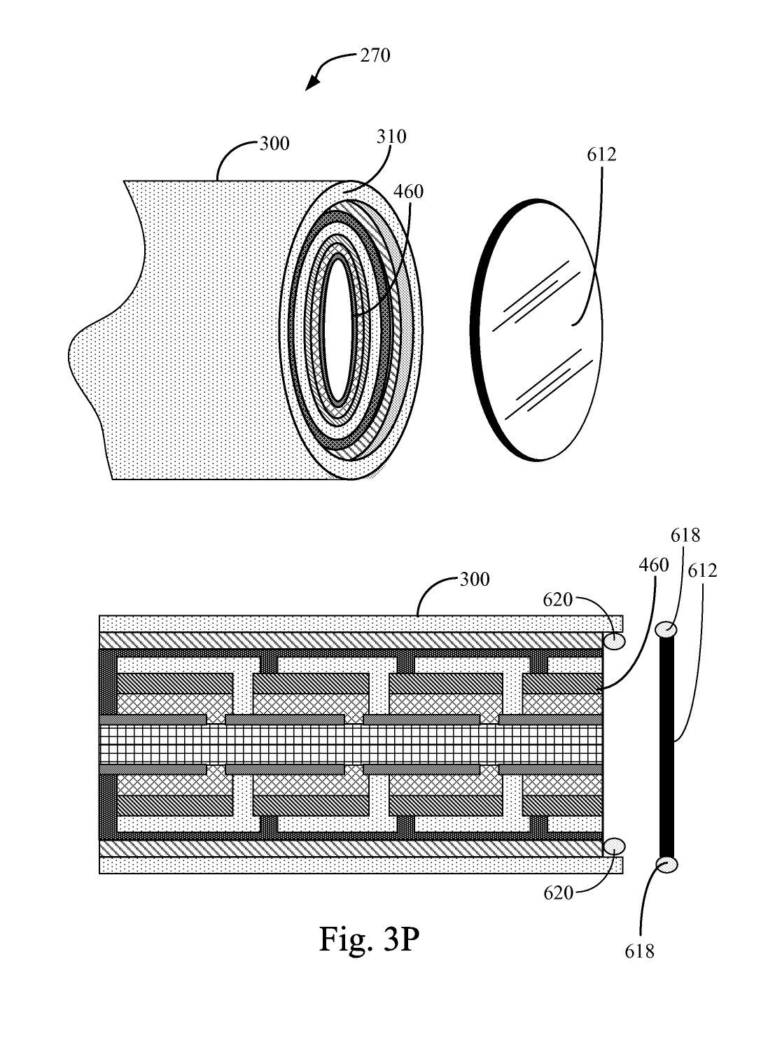

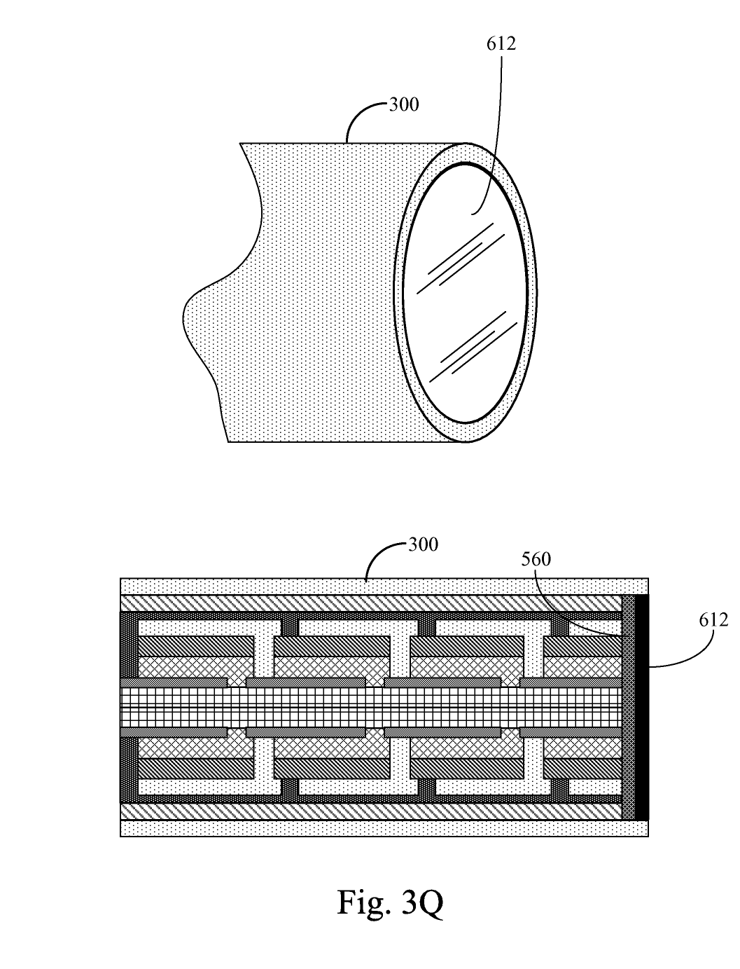

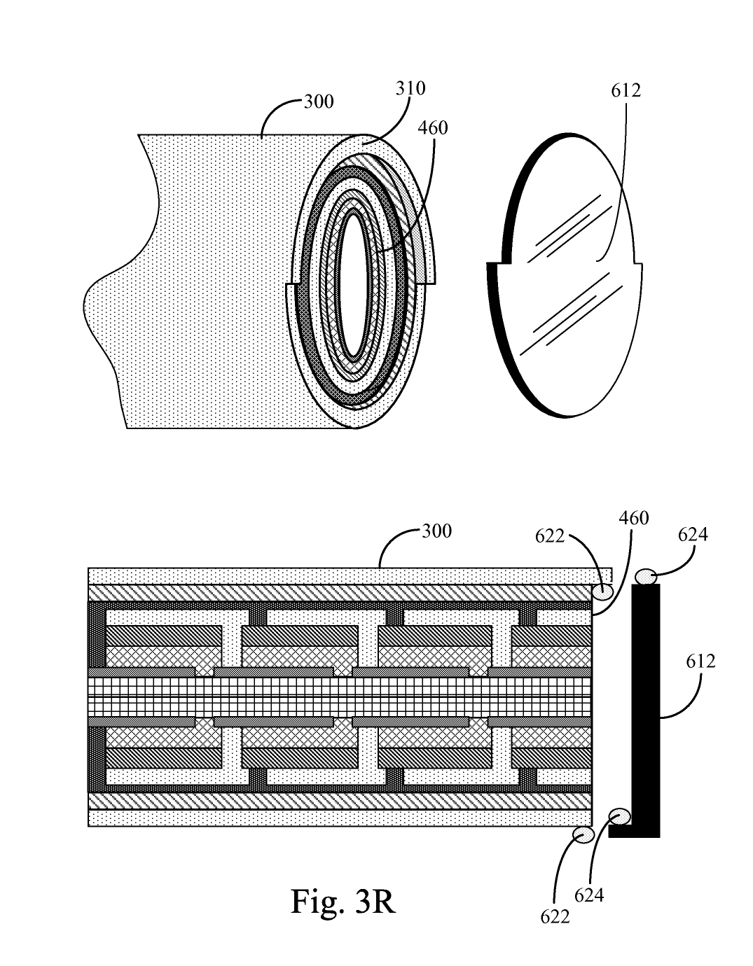

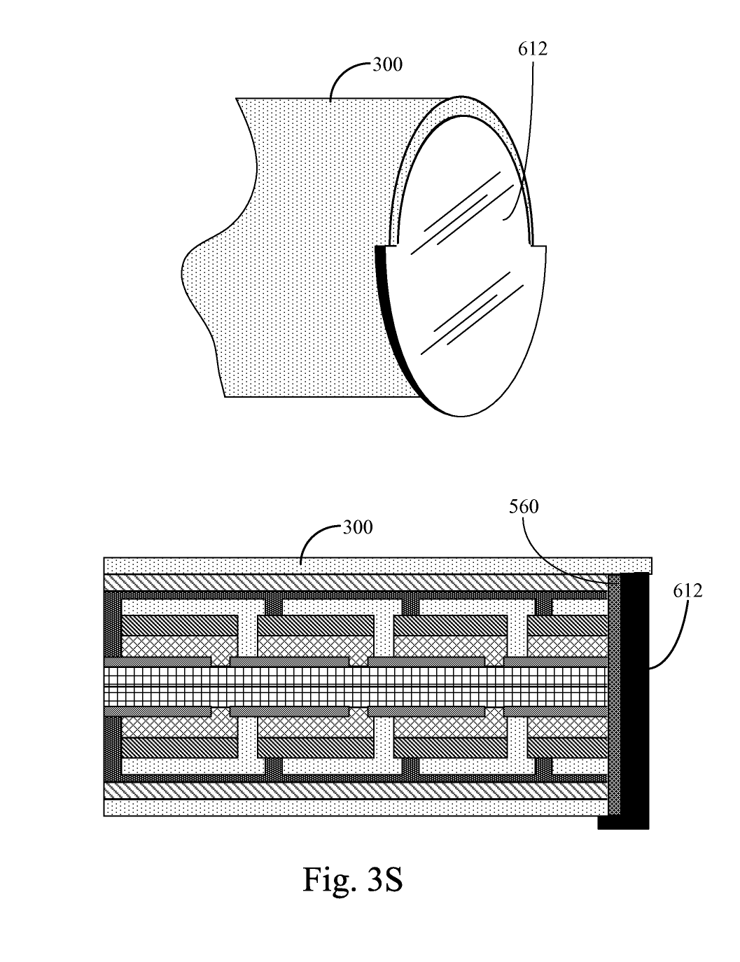

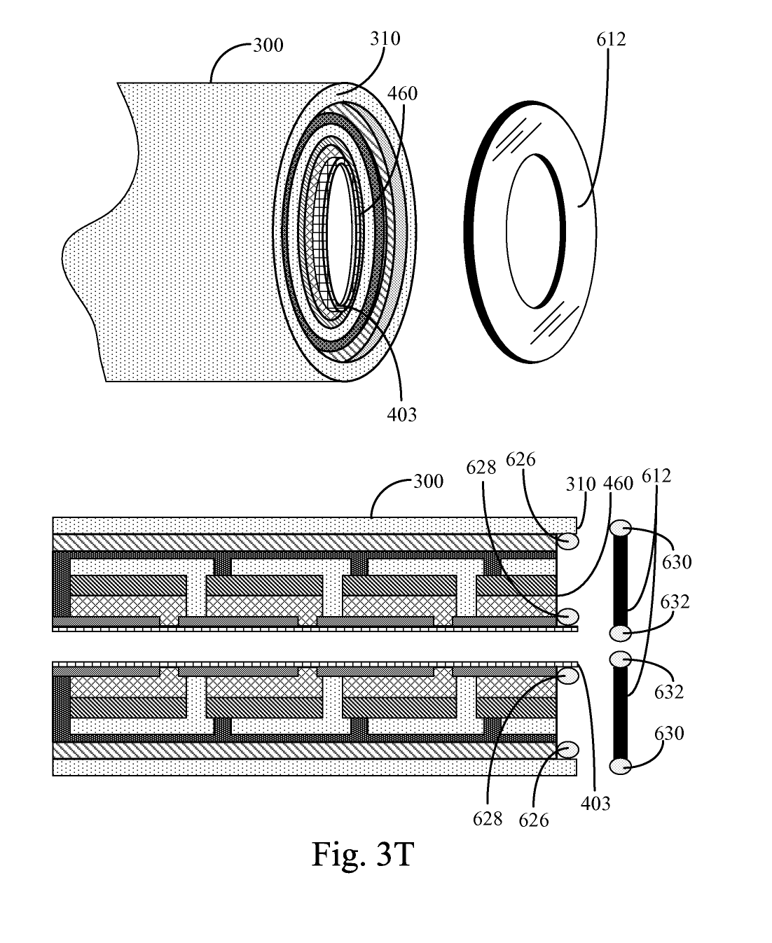

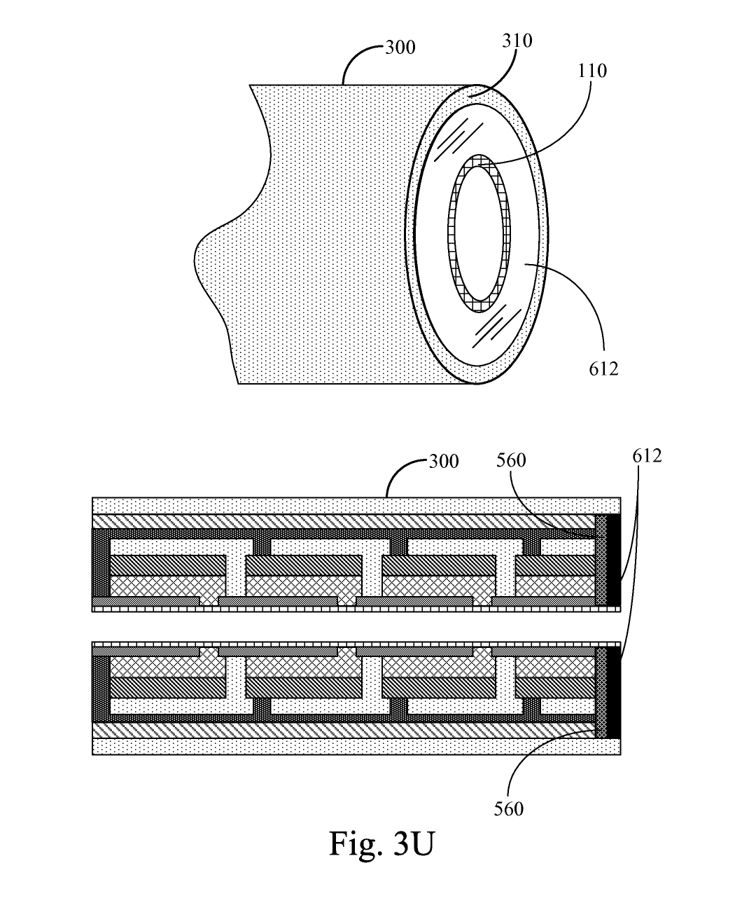

Optional filler layer 330. In some embodiments, as depicted in FIG. 3B, a filler layer 330 of sealant such as ethylene vinyl acetate (EVA), silicone, silicone gel, epoxy, polydimethyl siloxane (PDMS), RTV silicone rubber, polyvinyl butyral (PVB), thermoplastic polyurethane (TPU), a polycarbonate, an acrylic, a fluoropolymer, and/or a urethane is coated over the transparent conductive layer 110 to seal out air and, optionally, to provide complementary fitting to a transparent nonplanar casing 310. In some embodiments, the filler layer 330 is a Q-type silicone, a silsequioxane, a D-type silicon, or an M-type silicon. However, in some embodiments, the optional filler layer 330 is not needed even when one or more electrode strips 420 are present. In some embodiments the filler layer 330 is laced with a desiccant such as calcium oxide or barium oxide.

In some embodiments, the optional filler layer 330 is a laminate layer such as any of those disclosed in U.S. Provisional patent application No. 60/906,901, filed Mar. 13, 2007, entitled “A Photovoltaic Apparatus Having a Laminate Layer and Method for Making the Same” which is hereby incorporated by reference herein in its entirety for such purpose. In some embodiments the filler layer 330 has a viscosity of less than 1×106 cP. In some embodiments, the filler layer 330 has a thermal coefficient of expansion of greater than 500×10-6/° C. or greater than 1000×10-6/° C. In some embodiments, the filler layer 330 comprises polydimethylsiloxane polymer. In some embodiments, the filler layer 330 comprises by weight: less than 50% of a dielectric gel or components to form a dielectric gel; and at least 30% of a transparent silicon oil, the transparent silicon oil having a beginning viscosity of no more than half of the beginning viscosity of the dielectric gel or components to form the dielectric gel. In some embodiments, the filler layer 330 has a thermal coefficient of expansion of greater than 500×10-6/° C. and comprises by weight: less than 50% of a dielectric gel or components to form a dielectric gel; and at least 30% of a transparent silicon oil. In some embodiments, the filler layer 330 is formed from silicon oil mixed with a dielectric gel. In some embodiments, the silicon oil is a polydimethylsiloxane polymer liquid and the dielectric gel is a mixture of a first silicone elastomer and a second silicone elastomer. In some embodiments, the filler layer 330 is formed from X %, by weight, polydimethylsiloxane polymer liquid, Y %, by weight, a first silicone elastomer, and Z %, by weight, a second silicone elastomer, where X, Y, and Z sum to 100. In some embodiments, the polydimethylsiloxane polymer liquid has the chemical formula (CH₃)₃SiO[SiO(CH₃)₂]ₙSi(CH₃)₃, where n is a range of integers chosen such that the polymer liquid has an average bulk viscosity that falls in the range between 50 centistokes and 100,000 centistokes. In some embodiments, first silicone elastomer comprises at least sixty percent, by weight, dimethylvinyl-terminated dimethyl siloxane and between 3 and 7 percent by weight silicate. In some embodiments, the second silicone elastomer comprises: (i) at least sixty percent, by weight, dimethylvinyl-terminated dimethyl siloxane; (ii) between ten and thirty percent by weight hydrogen-terminated dimethyl siloxane; and (iii) between 3 and 7 percent by weight trimethylated silica. In some embodiments, X is between 30 and 90; Y is between 2 and 20; and Z is between 2 and 20.

In some embodiments, the filler layer 330 comprises a silicone gel composition, comprising: (A) 100 parts by weight of a first polydiorganosiloxane containing an average of at least two silicon-bonded alkenyl groups per molecule and having a viscosity of from 0.2 to 10 Pa·s at 25° C.; (B) at least about 0.5 part by weight to about 10 parts by weight of a second polydiorganosiloxane containing an average of at least two silicon-bonded alkenyl groups per molecule, wherein the second polydiorganosiloxane has a viscosity at 25° C. of at least four times the viscosity of the first polydiorganosiloxane at 25° C.; (C) an organohydrogensiloxane having the average formula R₇Si(SiOR⁸₂H)₃ wherein R⁷ is an alkyl group having 1 to 18 carbon atoms or aryl, R⁸ is an alkyl group having 1 to 4 carbon atoms, in an amount sufficient to provide from 0.1 to 1.5 silicon-bonded hydrogen atoms per alkenyl group in components (A) and (B) combined; and (D) a hydrosilylation catalyst in an amount sufficient to cure the composition as disclosed in U.S. Pat. No. 6,169,155, which is hereby incorporated by reference herein.

Transparent casing 310. The transparent casing 310 is disposed on the transparent conductive layer 110 and/or the optional filler layer 330. In some embodiments the casing 310 is made of plastic or glass. In some embodiments, the solar cells 402 are sealed in the transparent nonplanar casing 310. The transparent casing 310 fits over the outermost layer of the solar cells 402. In some embodiments, the solar cells 402 are inside the transparent casing 310. Methods, such as for example heat shrinking, injection molding, or vacuum loading, can be used to construct the transparent nonplanar casing 310 such that they exclude oxygen and water from the system as well as provide complementary fitting to the underlying solar cells 402.

In some embodiments, the transparent nonplanar casing 310 is made of a urethane polymer, an acrylic polymer, polymethylmethacrylate (PMMA), a fluoropolymer, silicone, poly-dimethyl siloxane (PDMS), silicone gel, epoxy, ethylene vinyl acetate (EVA), perfluoroalkoxy fluorocarbon (PFA), nylon/polyamide, cross-linked polyethylene (PEX), polyolefin, polypropylene (PP), polyethylene terephtalate glycol (PETG), polytetrafluoroethylene (PTFE), thermoplastic copolymer (for example, ETFE®, which is a derived from the polymerization of ethylene and tetrafluoroethylene: TEFLON® monomers), polyurethane/urethane, polyvinyl chloride (PVC), polyvinylidene fluoride (PVDF), TYGON®, vinyl, VITON®, or any combination or variation thereof.

In some embodiments, the transparent nonplanar casing 310 comprises a plurality of transparent tubular casing layers. In some embodiments, each transparent tubular casing is composed of a different material. For example, in some embodiments, the transparent nonplanar casing 310 comprises a first transparent tubular casing layer and a second transparent tubular casing layer. Depending on the exact configuration of the solar cell, the first transparent tubular casing layer is disposed on the transparent conductive layer 110, optional filler layer 330 or the water resistant layer. The second transparent tubular casing layer is disposed on the first transparent tubular casing layer.

In some embodiments, each transparent tubular casing layer has different properties. In one example, the outer transparent tubular casing layer has excellent UV shielding properties whereas the inner transparent tubular casing layer has good water proofing characteristics. Moreover, the use of multiple transparent tubular casing layers can be used to reduce costs and/or improve the overall properties of the transparent nonplanar casing 310. For example, one transparent tubular casing layer may be made of an expensive material that has a desired physical property. By using one or more additional transparent tubular casing layers, the thickness of the expensive transparent tubular casing layer may be reduced, thereby achieving a savings in material costs. In another example, one transparent tubular casing layer may have excellent optical properties (e.g., index of refraction, etc.) but be very heavy. By using one or more additional transparent tubular casing layers, the thickness of the heavy transparent tubular casing layer may be reduced, thereby reducing the overall weight of the transparent nonplanar casing 310.

Optional water resistant layer. In some embodiments, one or more layers of water resistant layer are coated over solar cells 402 for water proofing. In some embodiments, this water resistant layer is coated onto transparent conductive layer 110 prior to depositing optional filler layer 330 and encasing the solar cells 402 in the transparent nonplanar casing 310. In some embodiments, such water resistant layers are coated onto optional filler layer 330 prior to encasing the solar cells 402 in the transparent nonplanar casing 310. In some embodiments, such water resistant layers are coated onto the transparent nonplanar casing 310 itself. In embodiments where a water resistant layer is provided to seal water from solar cells 402, the optical properties of the water resistant layer do not interfere with the absorption of incident solar radiation by the solar cell 402. In some embodiments, this water resistant layer is made of clear silicone, SiN, SiOₓN_{y}, SiOₓ, or Al₂O₃, where x and y are integers. In some embodiments, the water resistant layer is made of a Q-type silicone, a silsequioxane, a D-type silicon, or an M-type silicon.

Optional antireflective coating. In some embodiments, an optional antireflective coating is also disposed on the transparent casing 310 to maximize solar cell efficiency. In some embodiments, there is a both a water resistant layer and an antireflective coating deposited on the transparent casing 310. In some embodiments, a single layer serves the dual purpose of a water resistant layer and an anti-reflective coating. In some embodiments, the antireflective coating is made of MgF₂, silicone nitrate, titanium nitrate, silicon monoxide (SiO), or silicon oxide nitrite. In some embodiments, there is more than one layer of antireflective coating. In some embodiments, there is more than one layer of antireflective coating and each layer is made of the same material. In some embodiments, there is more than one layer of antireflective coating and each layer is made of a different material.

In some embodiments, some of the layers of the multi-layered solar cells 402 are constructed using cylindrical magnetron sputtering techniques. In some embodiments, some of the layers of multi-layered solar cells 402 are constructed using conventional sputtering methods or reactive sputtering methods on long tubes or strips. Sputtering coating methods for long tubes and strips are disclosed in for example, Hoshi et al., 1983, “Thin Film Coating Techniques on Wires and Inner Walls of Small Tubes via Cylindrical Magnetron Sputtering,” Electrical Engineering in Japan 103:73-80; Lincoln and Blickensderfer, 1980, “Adapting Conventional Sputtering Equipment for Coating Long Tubes and Strips,” J. Vac. Sci. Technol. 17:1252-1253; Harding, 1977, “Improvements in a dc Reactive Sputtering System for Coating Tubes,” J. Vac. Sci. Technol. 14:1313-1315; Pearce, 1970, “A Thick Film Vacuum Deposition System for Microwave Tube Component Coating,” Conference Records of 1970 Conference on Electron Device Techniques 208-211; and Harding et al., 1979, “Production of Properties of Selective Surfaces Coated onto Glass Tubes by a Magnetron Sputtering System,” Proceedings of the International Solar Energy Society 1912-1916, each of which is hereby incorporated by reference herein in its entirety.

Optional fluorescent material. In some embodiments, a fluorescent material (e.g., luminescent material, phosphorescent material) is coated on a surface of a layer of solar cell unit 300. In some embodiments, the fluorescent material is coated on the luminal surface and/or the exterior surface of the transparent casing 310. In some embodiments, the fluorescent material is coated on the outside surface of transparent conductive oxide 110. In some embodiments, the solar cell unit 300 includes an optional filler layer 300 and the fluorescent material is coated on the optional filler layer. In some embodiments, the solar cell unit 300 includes a water resistant layer and the fluorescent material is coated on the water resistant layer. In some embodiments, more than one surface of a solar cell unit 300 is coated with optional fluorescent material. In some embodiments, the fluorescent material absorbs blue and/or ultraviolet light, which some semiconductor junctions 410 disclosed herein do not use to convert to electricity, and the fluorescent material emits light in visible and/or infrared light which is useful for electrical generation in some solar cell units 300 disclosed herein.

Fluorescent, luminescent, or phosphorescent materials can absorb light in the blue or UV range and emit visible light. Phosphorescent materials, or phosphors, usually comprise a suitable host material and an activator material. The host materials are typically oxides, sulfides, selenides, halides or silicates of zinc, cadmium, manganese, aluminum, silicon, or various rare earth metals. The activators are added to prolong the emission time.

In some embodiments, phosphorescent materials are incorporated in the disclosed systems and methods to enhance light absorption by the solar cell unit 300. In some embodiments, the phosphorescent material is directly added to the material used to make optional transparent casing 310. In some embodiments, the phosphorescent materials are mixed with a binder for use as transparent paints to coat various outer or inner layers of the solar cell unit 300, as described above.

Exemplary phosphors include, but are not limited to, copper-activated zinc sulfide (ZnS:Cu) and silver-activated zinc sulfide (ZnS:Ag). Other exemplary phosphorescent materials include, but are not limited to, zinc sulfide and cadmium sulfide (ZnS:CdS), strontium aluminate activated by europium (SrAlO₃:Eu), strontium titanium activated by praseodymium and aluminum (SrTiO₃:Pr, Al), calcium sulfide with strontium sulfide with bismuth ((Ca,Sr)S:Bi), copper and magnesium activated zinc sulfide (ZnS:Cu,Mg), or any combination thereof.

Methods for creating phosphor materials are known in the art. For example, methods of making ZnS:Cu or other related phosphorescent materials are described in U.S. Pat. Nos. 2,807,587 to Butler et al.; 3,031,415 to Morrison et al.; 3,031,416 to Morrison et al.; 3,152,995 to Strock; 3,154,712 to Payne; 3,222,214 to Lagos et al.; 3,657,142 to Poss; 4,859,361 to Reilly et al., and 5,269,966 to Karam et al., each of which is hereby incorporated by reference herein in its entirety. Methods for making ZnS:Ag or related phosphorescent materials are described in U.S. Pat. Nos. 6,200,497 to Park et al., 6,025,675 to Ihara et al.; 4,804,882 to Takahara et al., and 4,512,912 to Matsuda et al., each of which is hereby incorporated herein by reference in its entirety. Generally, the persistence of the phosphor increases as the wavelength decreases. In some embodiments, quantum dots of CdSe or similar phosphorescent material can be used to get the same effect. See Dabbousi et al., 1995, “Electroluminescence from CdSe quantum-dot/polymer composites,” Applied Physics Letters 66 (11): 1316-1318; Dabbousi et al., 1997 “(CdSe)ZnS Core-Shell Quantum Dots: Synthesis and Characterization of a Size Series of Highly Luminescent Nanocrystallites,” J. Phys. Chem. B, 101: 9463-9475; Ebenstein et al., 2002, “Fluorescence quantum yield of CdSe:ZnS nanocrystals investigated by correlated atomic-force and single-particle fluorescence microscopy,” Applied Physics Letters 80: 4033-4035; and Peng et al., 2000, “Shape control of CdSe nanocrystals,” Nature 404: 59-61; each of which is hereby incorporated by reference herein in its entirety.

In some embodiments, optical brighteners are used in the optional fluorescent layers disclosed herein. Optical brighteners (also known as optical brightening agents, fluorescent brightening agents or fluorescent whitening agents) are dyes that absorb light in the ultraviolet and violet region of the electromagnetic spectrum, and re-emit light in the blue region. Such compounds include stilbenes (e.g., trans-1,2-diphenylethylene or (E)-1,2-diphenylethene). Another exemplary optical brightener that can be used in the optional fluorescent layers disclosed herein is umbelliferone (7-hydroxycoumarin), which also absorbs energy in the UV portion of the spectrum. This energy is then re-emitted in the blue portion of the visible spectrum. More information on optical brighteners is in Dean, 1963, Naturally Occurring Oxygen Ring Compounds, Butterworths, London; Joule and Mills, 2000, Heterocyclic Chemistry, 4^{th} edition, Blackwell Science, Oxford, United Kingdom; and Barton, 1999, Comprehensive Natural Products Chemistry 2: 677, Nakanishi and Meth-Cohn eds., Elsevier, Oxford, United Kingdom, 1999.

Circumferentially disposed. In some embodiments of the apparatus disclosed herein, layers of material are successively circumferentially disposed on a substrate 403 in order to form a solar cell unit 300 comprising one or more solar cells 402. As used herein, the term “circumferentially disposed” is not intended to imply that each such layer of material is necessarily deposited on an underlying layer. In fact, the present disclosure teaches methods by which such layers are molded or otherwise formed on an underlying layer. Further, as discussed above in conjunction with the discussion of the substrate 403, the substrate and underlying layers may have any of several different nonplanar shapes. Nevertheless, the term “circumferentially disposed” means that an overlying layer is disposed on an underlying layer such that there is no annular space between the overlying layer and the underlying layer. Furthermore, as used herein, the term “circumferentially disposed” means that an overlying layer is disposed on at least fifty percent of the perimeter of the underlying layer. Furthermore, as used herein, the term “circumferentially disposed” means that an overlying layer is disposed along at least half of the length of the underlying layer.

Circumferentially sealed. As used herein, the term “circumferentially sealed”; is not intended to imply that an overlying layer or structure is necessarily deposited on an underlying layer or structure. In fact, disclosed herein are methods by which such layers or structures (e.g., transparent nonplanar casing 310) are molded or otherwise formed on an underlying layer or structure. Nevertheless, the term “circumferentially sealed” means that an overlying layer or structure is disposed on an underlying layer or structure such that there is no annular space between the overlying layer or structure and the underlying layer or structure. Furthermore, as used herein, the term “circumferentially sealed” means that an overlying layer is disposed on the full perimeter of the underlying layer. In typical embodiments, a layer or structure circumferentially seals an underlying layer or structure when it is circumferentially disposed around the full perimeter of the underlying layer or structure and along the full length of the underlying layer or structure. However, embodiments are disclosed in which a circumferentially sealing layer or structure does not extend along the full length of an underlying layer or structure.

Sealant cap 612. An advantage of the disclosed apparatus is that the ends 460 are sealed with a sealant cap (not shown in FIG. 2A). Examples of such sealant caps are disclosed, for example, in FIGS. 3N through 3U. Each illustration in FIGS. 3N-3U provides a perspective view of the solar cell unit 300. Below each perspective view is a corresponding cross-sectional view of the solar cell unit 300. In typical embodiments, the solar cell unit 300 illustrated in FIGS. 3N through 3U does not have an electrically conducting substrate 403. In the alternative, in embodiments where the substrate 403 is electrically conducting, an insulator layer is used such that the back-electrodes 104 of the individual solar cells 700 (402) are electrically isolated from each other. In some embodiments, a solar cell unit 300 comprises a single solar cell 402. In some embodiments, a solar cell unit 300 comprises a plurality of solar cells 402 (e.g., 5 or more solar cells 402, 10 or more solar cells 402, 50 or more solar cells 402, or 100 or more solar cells). In some embodiments, the solar cells 402 in a solar cell unit a monolithically integrated as illustrated in FIG. 3. However, the application is not limited to the monolithic integration embodiments illustrated in FIG. 3. Indeed any solar cell, whether monolithically integrated or not, can be sealed with the sealant caps disclosed herein. For instance, any of the solar cells described in U.S. patent application Ser. No. 11/378,847, hereby incorporated by reference herein in its entirety, can be sealed with sealant cap 612.

In some embodiments, there is a first sealant cap at a first end of the solar cell unit 300 and a second sealant cap at a second end of the solar cell unit 300, thereby sealing the solar cell unit 300 from water. For example, referring to FIGS. 3N and 3O, sealant cap 612 seals end 460 of solar cell unit 300. In the embodiment illustrated in FIGS. 3N and 3O, the sealant cap 612 is sealed onto the outer surface of transparent nonplanar casing 310. However, other configurations of the sealant cap 612 are possible. For example, referring to FIGS. 3P and 3Q, sealant cap 612 is sealed onto the inner surface of the transparent nonplanar casing 310. Mixed embodiments of the sealant cap 612 are possible as well. For example, referring to FIGS. 3R and 3S, a first portion of the cap 612 seals onto the inner surface of the transparent nonplanar casing 310 while a second portion of the cap 612 seals onto the outer surface of the transparent nonplanar casing 310. In FIGS. 3R and 3S, this first portion is approximately half the perimeter of the cap 612. However, in other embodiments, this first portion is some value other than half the perimeter of the cap 612. In some embodiments, the first portion is a quarter of the perimeter of the cap 612 and the second portion is three quarters of the perimeter of the cap 612. In some embodiments, the first portion is one percent or more, ten percent or more, twenty percent or more, thirty percent or more of the perimeter of the cap 612 and the second portion makes up the balance of cap 612. In some embodiments, the cap 612 comprises a plurality of first portions, where each first portion seals onto the inner surface of the transparent nonplanar casing 310, and a plurality of second portions, where each said second portion of the cap 612 seals onto the outer surface of the transparent nonplanar casing 310. In the embodiments illustrated in FIGS. 3T and 3U, the sealant cap 612 is sealed onto the inner surface of the transparent nonplanar casing 310 and the outer surface of the substrate 403. In FIGS. 3T and 3U, the substrate 403 is hollowed. In other embodiments, however, the substrate 403 is solid, with no hollow core.

Still other configurations of the sealant cap 612 are possible. For example, in some embodiments, the sealant cap 612 is bonded onto the outer surface of the transparent nonplanar casing 310 and the outer surface of the substrate 403. In some embodiments, the sealant cap 612 is bonded onto the outer surface of the transparent nonplanar casing 310 and the inner surface of substrate 403. In some embodiments, the sealant cap 612 is bonded onto the inner surface of the transparent nonplanar casing 310 and the inner surface of substrate 403.

In some embodiments, all or a portion of the sealant cap 612 is solid rod shaped, and/or characterized by a cross-section bounded by any one of a number of shapes. The cross-sectional bounding shape can be, for example, any one of circular, ovoid, or any shape characterized by one or more smooth curved surfaces, or any splice of smooth curved surfaces. The cross-sectional bounding shape can be an n-gon, where n is 3, 4, 5, or greater than 5. The cross-sectional bounding shape can also be linear in nature, including triangular, pentangular, hexagonal, or having any number of linear segmented surfaces. Or, the cross-section can be bounded by any combination of linear surfaces, arcuate surfaces, or curved surfaces. In some embodiments, solar cell unit 300 is cylindrical or approximately cylindrical shape. In some embodiments, the sealant cap 612 is characterized by an irregular cross-section so long as the sealant cap 612, taken as a whole, is roughly cylindrical. Such cylindrical shapes can be solid (e.g., a rod) or hollowed (e.g., a tube).

Advantageously, in some embodiments, the metal(s) that are typically used to make the sealant cap 612 are chosen to match the thermal expansion coefficient of the glass. For example, in some embodiments, the transparent casing 310 is made of soda lime glass (CTE of about 9 ppm/C) and the sealant cap 612 is made of a low expansion stainless steel alloy like 410 (CTE of about 10 ppm/C). In some embodiments, the transparent casing 310 is made of borosilicate glass (CTE of about 3.5 ppm/C) and sealant cap 612 is made of Kovar (CTE of about 5 ppm/C). Kovar is an iron-nickel-cobalt alloy. In some embodiments, the sealant cap 612 is composed of any conductive material, such as aluminum, molybdenum, tungsten, vanadium, rhodium, niobium, chromium, tantalum, titanium, steel, nickel, platinum, silver, gold, an alloy thereof (e.g. Kovar), or any combination thereof. In some embodiments, the sealant cap 612 is composed of any waterproof conductive material, such as indium tin oxide, titanium nitride, tin oxide, fluorine doped tin oxide, doped zinc oxide, aluminum doped zinc oxide, gallium doped zinc oxide, boron dope zinc oxide, or indium-zinc oxide. In some embodiments, the sealant cap 612 is made of aluminosilicate glass, borosilicate glass (e.g., Pyrex, Duran, Simax, etc.), dichroic glass, germanium/semiconductor glass, glass ceramic, silicate/fused silica glass, soda lime glass, quartz glass, chalcogenide/sulphide glass, fluoride glass, pyrex glass, a glass-based phenolic, cereated glass, or flint glass.

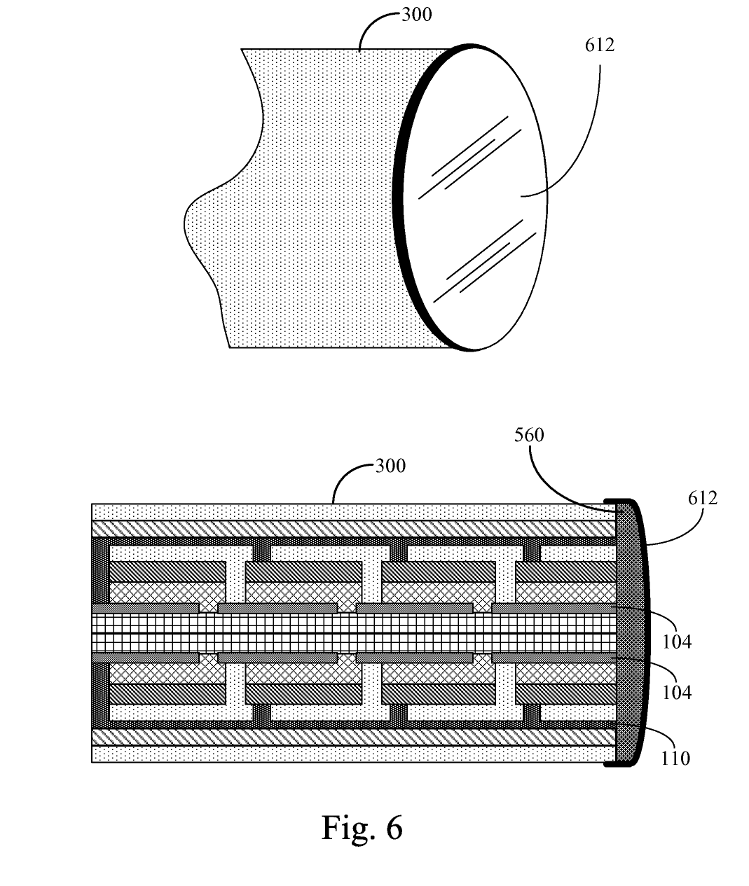

In embodiments where the sealant cap 612 is made of metal, care is taken to make sure that the sealant cap does not form an electrical connection with both the transparent conductive layer 110 and the back-electrode 104. This can be accomplished in any number of ways. In the embodiment illustrated in FIGS. 3N and 3O, a filler layer 560 is positioned between the end 460 and the sealant cap 612. The filler layer 560 electrically isolates the sealant cap 612 from the transparent conductive layer 110 and back-electrode 104. In some embodiments filler layer 560 comprises ethylene vinyl acetate (EVA), silicone, silicone gel, epoxy, polydimethyl siloxane (PDMS), RTV silicone rubber, polyvinyl butyral (PVB), thermoplastic polyurethane (TPU), a polycarbonate, an acrylic, a fluoropolymer, and/or a urethane. In some embodiments, the filler layer 560 is a Q-type silicone, a silsequioxane, a D-type silicon, or an M-type silicon. In some embodiments, the filler layer 560 comprises EVA, silicone rubber, or solid rubber. In some embodiments the filler layer is laced with a desiccant such as calcium oxide or barium oxide. In some embodiments, in addition to using the filler layer 560, the sealant cap 612 is shaped so that it will not contact the transparent conductive layer 110 and the back-electrode 104. One such shape for the sealant cap 612 is illustrated in FIG. 6. As can be seen in FIG. 6, the sealant cap 612 is bowed out relative to the solar cell unit 300 so that it does not make electrical contact with the transparent conductive layer 110 and the back-electrode 104. FIG. 6 merely serves to illustrate the point that the sealant cap 612 can adopt any type of shape so long at it makes a seal with the solar cell unit 300.

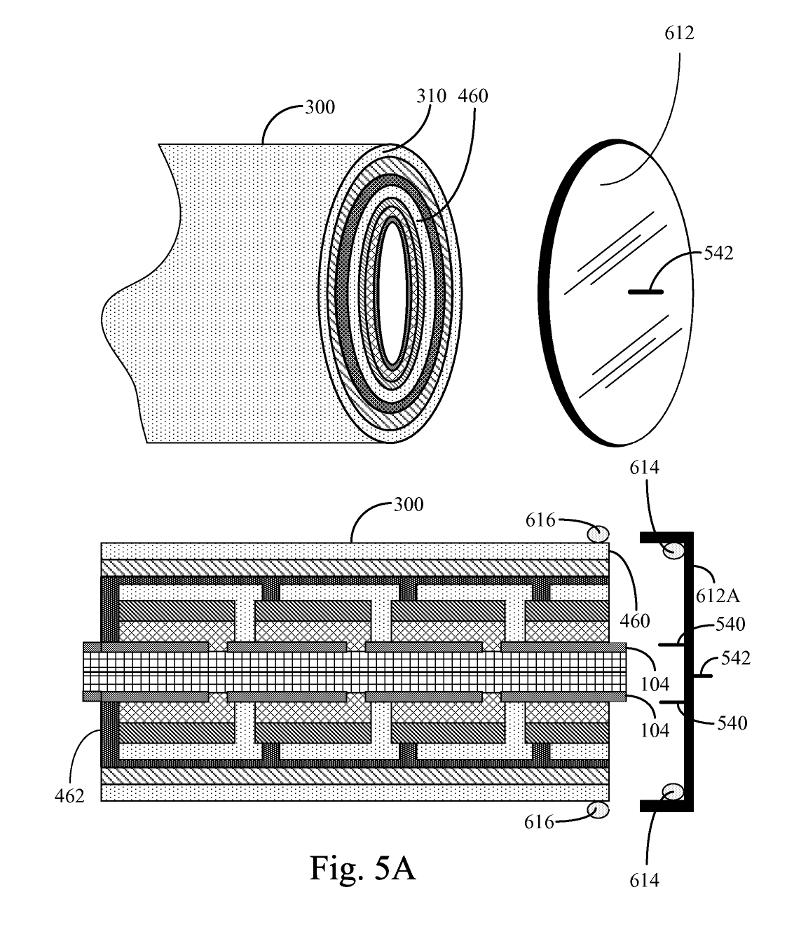

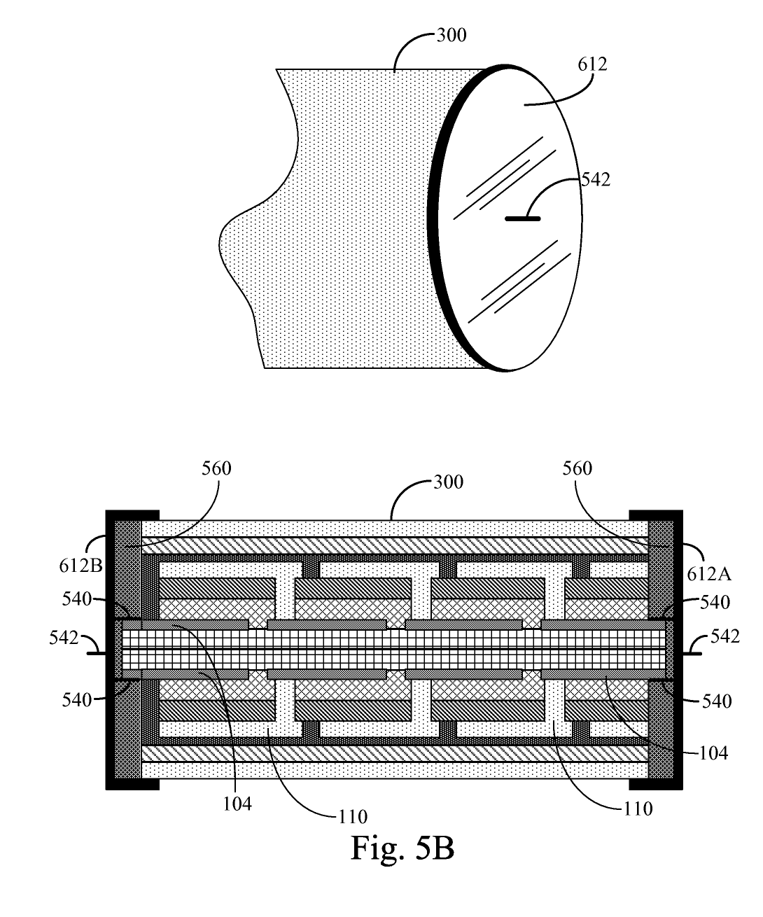

Advantageously, the sealant cap 612 can serve as an electrical lead for either the transparent conductive layer 110 or the back-electrode 104. Thus, in some embodiments, a first end of the solar cell unit 300 is sealed with a first sealant cap 612 that makes an electrical connection with the transparent conductive layer 110 and the second end of the solar cell unit 300 is sealed with a second sealant cap 612 that makes an electrical connection with the back-electrode 104. More typically, a first end of the solar cell unit 300 is sealed with a first sealant cap 612 that makes an electrical connection with the back-electrode 104 that is electrical communication with the transparent conductive layer 110 while a second end of the solar cell unit 300 is sealed with a second sealant cap 612 that makes an electrical connection with the back-electrode 104 that is electrically isolated from the transparent conductive layer 110. For example, referring to FIG. 5B, in some embodiments, a first sealant cap 612A makes an electrical connection with the back-electrode 104 that is in electrical communication with the transparent conductive layer 110 and a second sealant cap 612B makes an electrical connection with the back-electrode 104 that is electrically isolated from the transparent conductive layer 110. In these embodiments, the first sealant cap 612 serves as the electrode for transparent conductive layer 110 while the second sealant cap 612 serves as the electrode for the back-electrode 104. Referring to FIGS. 3N and 3O, for example, in embodiments where the sealant cap 612 is made of metal, electrical contact between the sealant cap 612 and both the transparent conductive layer 110 and the back-electrode 104 is not made. Thus, in embodiments where the sealant cap 612 is made of metal, the sealant cap 612 is electrically isolated from at least one of the transparent conductive layer 110 and the back-electrode 104.

Referring to FIG. 5A, in one example, the sealant cap 612A includes the electrical contacts 540 that are positioned within the sealant cap 612A so that they form electrical contact with the back-electrode 104 (as illustrated in FIG. 5A). Then the lead 542 serves as the electrical lead for the transparent conductive layer 110 (as illustrated in FIG. 5A) since the transparent conductive layer 110 is in electrical communication with the back-electrode 104 at the point of contact of electrode 540. Referring to FIG. 5B, sealant cap 612A is sealed onto the solar cell unit 300 using the sealant 614 and/or 616. As a result, the electrical contacts 540 make electrical contact with the back-electrode 104. In preferred embodiments, the space 560 is filled with a non-conducting filler such as ethylene vinyl acetate (EVA), silicone, silicone gel, epoxy, polydimethyl siloxane (PDMS), RTV silicone rubber, polyvinyl butyral (PVB), thermoplastic polyurethane (TPU), a polycarbonate, an acrylic, a fluoropolymer, or a urethane, before sealing the sealant cap 612 onto the solar cell unit to prevent encapsulation of air within the solar cell. In some embodiments, the electrical contacts 540 are fitted onto the back-electrode 104 rather than onto the sealant cap 612. In some embodiments, the electrical contacts 540 are simply an extension of the back-electrode 104.

In some embodiments the sealant cap 612 is made of glass. In such embodiments, there is a lead for the transparent conductive layer 110 or the back-electrode 104 through the sealant cap 612 (not shown). In such embodiments, the sealant cap 612 can abut directly against the side ends 460. Thus, in such embodiments, the filler layer 560 is optional.

In some embodiments, the sealant cap 612 is sealed onto solar cell unit using butyl rubber (e.g., polyisobutylene). In such embodiments, the filler layer 560 is butyl rubber and glass fits or ceramics are not required to seal the sealant cap 612 onto the solar cell unit 300 because the butyl rubber performs this function. In some embodiments, this butyl rubber is loaded with active desiccant such as CaO or BaO. In such embodiments that are sealed with butyl rubber, the solar cell unit has a water vapor transmission rate of less than 10⁻⁴ g/m²·day. In some embodiments that use butyl rubber for the filler layer 560, the sealant cap 612 is not required. In such embodiments, the ends of solar cell unit 300 are sealed with butyl rubber. In embodiments where butyl rubber is used without the sealant cap 612 leads such as leads 540 and 542 of FIG. 5A can be used to electrically connect the solar cell unit 300 with other solar cell units 300 or other circuitry.

In some embodiments the sealant cap 612 is sealed onto the solar cell unit 300 using glass-to-glass, metal-to-metal, ceramic-to-metal, or glass-to-metal seals. There are two exemplary types of glass-to-metal hermetic seals used in various exemplary embodiments: matched seals and mismatched (compression) seals. Matched glass-to-metal hermetic seals are made of metal alloys and the substrate 403/transparent casing 310 that share similar thermal expansion characteristics. Mismatched or compression glass to metal hermetic seals feature a steel or stainless steel sealant cap 612 that has a higher thermal expansion rate than the glass solar cell. Upon cooling, the sealant cap 612 contracts around the glass, creating a hermetic seal that is reinforced both chemically and mechanically. In some embodiments, a hermetic seal is any seal that has a water vapor transmission rate of 10⁻⁴ g/m²·day or better. In some embodiments, a hermetic seal is any seal that has a water vapor transmission rate of 10⁻⁵ g/m²·day or better. In some embodiments, a hermetic seal is any seal that has a water vapor transmission rate of 10⁻⁶ g/m²·day or better. In some embodiments, a hermetic seal is any seal that has a water vapor transmission rate of 10⁻⁷ g/m²·day or better. In some embodiments, a hermetic seal is any seal that has a water vapor transmission rate of 10⁻⁸ g/m²·day or better.

In some embodiments, the seal formed between the sealant cap 612 and the solar cell unit 300 has a water vapor transmission rate (WVTR) of 10⁻⁴ g/m²·day or less. In some embodiments, the seal formed between the sealant cap 612 and the solar cell unit 300 has a water vapor transmission rate (WVTR) of 10⁻⁵ g/m²·day or less. In some embodiments, the seal formed between the cap 612 and the solar cell unit 300 has a WVTR of 10⁻⁶ g/m²·day or less. In some embodiments, the seal formed between the cap 612 and the solar cell unit 300 has a WVTR of 10⁻⁷ g/m²·day or less. In some embodiments, the seal formed between the cap 612 and the solar cell unit 300 has a WVTR of 10⁻⁸ g/m²·day or less. The seal between the sealant cap 612 and the solar cell unit 300 can be accomplished using a glass or, more generally, a ceramic material. In preferred embodiments, this glass or ceramic material has a melting temperature between 200° C. and 450° C. In some embodiments, this glass or ceramic material has a melting temperature between 300° C. and 450° C. In some embodiments, this glass or ceramic material has a melting temperature between 350° C. and 400° C. There are a wide range of glasses and ceramic materials that can be used to form the hermetic seal. Examples include, but are not limited to, oxide ceramics including alumina, zirconia, silica, aluminum silicate, magnesia and other metal oxide based materials, ceramics based upon aluminum dioxide, aluminum nitrate, aluminum oxide, aluminum zirconia, as well as glasses based upon silicon dioxide.

Referring to FIG. 3N, in some embodiments, the sealant cap 612 is sealed onto the solar cell unit 300 by placing a continuous strip of sealant 614 around the inner edge of the sealant cap 612. Still referring to FIG. 3N, in some embodiments, a continuous strip of sealant 616 is placed on the outer edge of the transparent casing 310. Typically, the sealant 614 (around inner edge of sealant cap 612) or the sealant 616 (around outer edge of transparent casing 310), but not both, are used.

In some embodiments, the sealant 614 and/or sealant 616 is glass frit. There are different types of frit which can be used for different types of glass and at different temperatures. The disclosed apparatus are independent of the frit or glass type. In some embodiments, the glass frit has a melting temperature between 200° C. and 450° C. Such materials, also called solder glass, are available from many sources, including Ferro Corporation (Cleveland, Ohio), Schott Glass (Elmsford, N.Y.), and Asahi Glass (Tokyo, Japan). Advantageously, the use of low temperature melting solder glass limits the exposure of the active components of the solar cell unit 300 to extreme temperature during formation of the seal. In some embodiments, the glass frit is a pressed or sintered preform made to the correct shape of the application (either to fit over outer edge of transparent nonplanar casing 310 in the case of sealant 616 or to fit within the inner edge of sealant cap 612 in the case of sealant 614). In some embodiments, the solder glass is suspended in an organic binder material or is applied as a dry powder. In embodiments where the sealant 614 and/or 616 is glass frit, the temperature is increased to a value that will enable the continuous glass frit to soften. Heat can be applied by methods such as direct contact with a hot surface, by inductively heating up a metal part, by contact with flame or hot air, or through absorption of light from a laser. Once the glass frit is softened, the sealant cap 612 is pressed onto the solar cell unit 300. The softened glass frit forms a bond with the parts being joined, thus forming a hermetic seal.

In some embodiments, the sealant 614 and/or sealant 616 is a sol-gel material. As is known, a sol-gel material alternates between two states, one being a colloidal suspension of solid particles in a liquid, the other state being a dual phase material in which there is a solid outer shell filled with a solvent. When the solvent is removed, e.g., through exposure to ambient atmospheric pressure, a xerogel material results with a consistency similar to that of a low density glass. As is also known, a sol-gel material may be formulated by combining a quantity of potassium silicate (kasil) (e.g., 120 grams) with a comparatively smaller quantity of formamide (e.g., 7-8 grams). Alternatively, a lesser quantity of kasil (e.g., 12 grams) may be combined with still a lesser quantity of propylene carbonate (e.g., 2-3 grams). Another method of forming a sol-gel material involves the mixture of TEOS—H₂O and methanol, and allowing the mixture to hydrolyse. In embodiments where the sealant 614 and/or 616 is sol-gel, the sealant cap 612 is pressed onto the solar cell unit 300 and the sol-gel is allowed to cure. In some embodiments, the sol-gel is cured at ambient temperature and ambient atmospheric pressure. Alternatively, the curing process may be accelerated by other methods such as, e.g., applying heat or using an infrared heat source. In the case where the sol-gel is a polycarbonate-kasil mixture, the sol-gel material cures in approximately 5 to 10 minutes at room temperature. Sol-gels are discussed in Madou, 2002, Fundamentals of Microfabrication, The Science of Miniaturization, Second Edition, CRC Press, New York, pp. 156-157, which is hereby incorporated by reference herein in its entirety.

In some embodiments, the sealant 614 and/or sealant 616 is a ceramic cement material. Such materials are readily available from suppliers such as Aremco (Valley Cottage, N.Y.) and Sauereisen (Pittsburgh, Pa.). Such materials are relatively inexpensive and provide strong bonds to glass or metal. By their nature, however, these cements form porous ceramics which do not provide a hermetic waterproof seal. However, such materials can be waterproofed. A suspension of solder glass particles which are smaller than the pore size of the ceramic can be made in a volatile liquid. This liquid can then be allowed to wick into the pores of the ceramic by capillary action. Subsequent heating causes the solder glass to melt, thus wetting the ceramic material, and thereby sealing the ceramic and forming a hermetic seal. Aremco sells a product for this application (AremcoSeal 617). AremcoSeal 617 glass, however, has the drawback that it must be treated at high temperature. Thus, in some embodiments, a low melting point solder glass suspended in a binder such as provided by DieMat (DM2700P sealing glass paste) is used instead. Both the porous ceramics and the sol-gel can be waterproofed using these techniques.

In one embodiment in accordance with FIGS. 3N and 3O, DM2700P (DieMat, Byfield, Mass.) is coated onto the outer perimeter of the transparent nonplanar casing 310 to form the sealant 616 and the paste is allowed to dry. Then, the sealant cap 612, made of stainless steel, is heated on a hotplate to about 420° C. Next, the coated end of the solar cell unit 300 is manually inserted into the hot cap, while still on the hotplate. The sealing glass paste is allowed to melt and wet the surface of the sealant cap 612. The solar cell unit 300 is removed from the hotplate and allowed to cool.

In another embodiment in accordance with FIGS. 3N and 3O, DM2700P coating is applied to the inner perimeter of the sealant cap 612 in order to form the sealant 614. The paste is allowed to dry. Next, the stainless steel cap is heated on a hotplate to about 420° C. until the sealing glass melts. One end of the solar cell unit 300 is manually inserted into the stainless steal cap while the cap is still on the hotplate. The sealing glass paste melts and wets the outer surface of surface of the transparent nonplanar casing 310. The assembly is then removed from the hotplate and allowed to cool.

Referring to FIG. 3P, the sealant 618 and/or 620 is used to seal the sealant cap 612 to the solar cell unit 300. The sealant 618 and/or 620 is made of any of the compositions that can be used to make the sealant 614 and/or 616 described above. Referring to FIG. 3R, the sealant 622 and/or 624 is used to seal the sealant cap 612 to the solar cell unit 300. The sealant 622 and/or 624 is made of any of the compositions that can be used to make the sealant 614 and/or 616 described above. Referring to FIG. 3T, the sealant 626 and/or 630 together with the sealant 628 and/or sealant 632 is used to seal the sealant cap 612 to the solar cell unit 300. The sealant 626 and/or 628 and/or 630 and/or 632 is made of any of the compositions that can be used to make the sealant 614 and/or 616 described above.

### 5.1.1 Manufacture of Monolithic Solar Cells on a Substrates

FIGS. 3A-3K illustrate exemplary processing steps for manufacturing a solar cell unit 300 using a cascading technique. Other manufacturing techniques for manufacturing monolithically integrated solar cells, and other forms of monolithically integrated solar cells that can be used in the present application are disclosed in U.S. patent application Ser. No. 11/378,835, filed Mar. 18, 2006, which is hereby incorporated by reference herein in its entirety. Each illustration in FIGS. 3A-3K shows the perspective view of the solar cell unit 300 in various stages of manufacture. Below each perspective view is a corresponding cross-sectional view of one hemisphere of the corresponding solar cell unit 300. In typical embodiments, the solar cell unit 300 illustrated in FIG. 3 does not have an electrically conducting substrate 403. In the alternative, in embodiments where the substrate 403 is electrically conducting, the substrate is wrapped with an insulator layer so that the back-electrodes 104 of individual solar cells 700 (402) are electrically isolated from each other.

Referring to FIG. 3K, the solar cell unit 300 comprises a substrate 403 common to a plurality of photovoltaic cells 700. The substrate 403 has a first end and a second end. The plurality of photovoltaic cells 700 are linearly arranged on the substrate 403 as illustrated in FIG. 3K. The plurality of photovoltaic cells 700 comprises a first and second photovoltaic cell 700. Each photovoltaic cell 700 in the plurality of photovoltaic cells 700 comprises a back-electrode 104 disposed on common substrate 403 and a semiconductor junction 406 disposed on the back-electrode 104. In the case of FIG. 3K, the semiconductor junction 406 comprises an absorber 106 and a window layer 108. Each photovoltaic cell 700 in the plurality of photovoltaic cells 700 further comprises a transparent conductive layer 110 disposed on the semiconductor junction 406. In the case of FIG. 3K, the transparent conductive layer 110 of the first photovoltaic cell 700 is in serial electrical communication with the back-electrode of the second photovoltaic cell in the plurality of photovoltaic cells because of vias 280. In some embodiments, each via 280 extends the full perimeter of the solar cell. In some embodiments, each via 280 does not extend the full perimeter of the solar cell. In fact, in some embodiments, each via only extends a small percentage of the perimeter of the solar cell. In some embodiments, each solar cell 700 may have one, two, three, four or more, ten or more, or one hundred or more vias 280 that electrically connect in series the transparent conductive layer 110 of the solar cell 700 with back-electrode 104 of an adjacent solar cell 700.

An exemplary process for manufacturing an exemplary solar cell unit 300 will now be described in conjunction with FIGS. 3A through 3K. In this description, exemplary materials for each component of the solar cell unit 300 will be described. However, a more comprehensive description of the suitable materials for each component of solar cell unit 300 is provided in Section 5.1 above. Referring to FIG. 3A, the process begins with the substrate 403. Next, in FIG. 3B, back-electrode 104 is disposed on the substrate 403. The back-electrode 104 may be deposited by a variety of techniques, including any of the techniques disclosed in U.S. patent application Ser. No. 11/378,835, filed Mar. 18, 2006. In some embodiments, the back-electrode 104 is disposed on the substrate 403 by sputtering. In some embodiments, the back-electrode 104 is disposed on the substrate 403 by electron beam evaporation. In some embodiments, the substrate 403 is made of a conductive material. In such embodiments, it is possible to dispose the back-electrode 104 onto the substrate 403 using electroplating. In some embodiments, the substrate 403 is not electrically conducting but is wrapped with a metal foil such as a steal foil or a titanium foil. In such embodiments, it is possible to electroplate the back-electrode 104 onto the metal foil using electroplating techniques. In still other embodiments, the back-electrode 104 is disposed on the substrate 403 by hot dipping.

Referring to FIG. 3C, the back-electrode 104 is patterned in order to create the grooves 292. The grooves 292 run the full perimeter of the back-electrode 104, thereby breaking the back-electrode 104 into discrete sections. Each section serves as the back-electrode 104 of a corresponding solar cell 700. The bottoms of the grooves 292 expose the underlying substrate 403. In some embodiments, the grooves 292 are scribed using a laser beam having a wavelength that is absorbed by the back-electrode 104. Laser scribing provides many advantages over traditional methods of machine cutting. When processing thin films using a laser, the terms laser scribing, etching and ablation are used inter-changeably. Laser cutting of metal materials can be divided into two main methods: vaporization cutting and melt-and-blow cutting. In vaporization cutting, the material is rapidly heated to vaporization temperature and removed spontaneously as vapor. The melt-and-blow method heats the material to melting temperature while a jet of gas blows the melt away from the surface. In some embodiments, an inert gas (e.g., Ar) is used. In other embodiments, a reactive gas is used to increase the heating of the material through exothermal reactions with the melt. The thin film materials processed by laser scribing techniques include the semiconductors (e.g., cadmium telluride, copper indium gallium diselenide, and silicon), the transparent conducting oxides (e.g., fluorinedoped tin oxide and aluminum-doped zinc oxide), and the metals (e.g., molybdenum and gold). Such laser systems are all commercially available and are chosen based on pulse durations and wavelength. Some exemplary laser systems that may be used to laser scribe include, but are not limited to, Q-switched Nd:YAG laser systems, a Nd:YAG laser systems, copper-vapor laser systems, a XeCl-excimer laser systems, a KrFexcimer laser systems, and diode-laser-pumped Nd:YAG systems. See Compaan et al., 1998, “Optimization of laser scribing for thin film PV module,” National Renewable Energy Laboratory final technical progress report April 1995-October 1997; Quercia et al., 1995, “Laser patterning of CuInSe₂/Mo/SLS structures for the fabrication of CuInSe₂ sub modules,” in Semiconductor Processing and Characterization with Lasers: Application in Photovoltaics, First International Symposium, Issue 173/174, Number com P: 53-58; and Compaan, 2000, “Laser scribing creates monolithic thin film arrays,” Laser Focus World 36: 147-148, 150, and 152, for exemplary detailed laser scribing systems and methods that can be used. In some embodiments, the grooves 292 are scribed using mechanical means. For example, a razor blade or other sharp instrument is dragged over the back-electrode 104 thereby creating the grooves 292. In some embodiments the grooves 292 are formed using a lithographic etching method.

FIGS. 3D-3F illustrate the case in which the semiconductor junction 406 comprises a single absorber layer 106 and a single window layer 108. However, the present disclosure is not so limited. For example, the semiconductor junction 406 can be a homojunction, a heterojunction, a heteroface junction, a buried homojunction, a p-i-n junction, or a tandem junction. Referring to FIG. 3D, the absorber layer 106 is disposed on the back-electrode 104. In some embodiments, the absorber layer 106 is deposited onto the back-electrode 104 by thermal evaporation. For example, in some embodiments, the absorber layer 106 is CIGS that is deposited using techniques disclosed in Beck and Britt, Final Technical Report, January 2006, NREL/SR-520-39119; and Delahoy and Chen, August 2005, “Advanced CIGS Photovoltaic Technology,” subcontract report; Kapur et al., January 2005 subcontract report, NREL/SR-520-37284, “Lab to Large Scale Transition for Non-Vacuum Thin Film CIGS Solar Cells”; Simpson et al., October 2005 subcontract report, “Trajectory-Oriented and Fault-Tolerant-Based Intelligent Process Control for Flexible CIGS PV Module Manufacturing,” NREL/SR-520-38681; and Ramanathan et al., 31^{st} IEEE Photovoltaics Specialists Conference and Exhibition, Lake Buena Vista, Fla., Jan. 3-7, 2005, each of which is hereby incorporated by reference herein in its entirety. In some embodiments, the absorber layer 106 is deposited on the back-electrode 104 by evaporation from elemental sources. For example, in some embodiments, the absorber layer 106 is CIGS grown on a molybdenum back-electrode 104 by evaporation from elemental sources. One such evaporation process is a three stage process such as the one described in Ramanthan et al., 2003, “Properties of 19.2% Efficiency ZnO/CdS/CuInGaSe₂ Thin-film Solar Cells,” Progress in Photovoltaics: Research and Applications 11, 225, which is hereby incorporated by reference herein in its entirety, or variations of the three stage process. In some embodiments, the absorber layer 106 is deposited onto the back-electrode 104 using a single stage evaporation process or a two stage evaporation process. In some embodiments, the absorber layer 106 is deposited onto the back-electrode 104 by sputtering. Typically, such sputtering requires a hot substrate 403.

In some embodiments, the absorber layer 106 is deposited onto the back-electrode 104 as individual layers of component metals or metal alloys of the absorber layer 106 using electroplating. For example, consider the case where the absorber layer 106 is copper-indium-gallium-diselenide (CIGS). The individual component layers of CIGS (e.g., copper layer, indium-gallium layer, selenium) can be electroplated layer by layer onto the back-electrode 104. In some embodiments, the individual layers of the absorber layer are deposited onto the back-electrode 104 using sputtering. Regardless of whether the individual layers of the absorber layer 106 are deposited by sputtering or electroplating, or a combination thereof, in typical embodiments (e.g. where the active layer 106 is CIGS), once component layers have been deposited, the layers are rapidly heated up in a rapid thermal processing step so that they react with each other to form the absorber layer 106. In some embodiments, the selenium is not delivered by electroplating or sputtering. In such embodiments the selenium is delivered to the absorber layer 106 during a low pressure heating stage in the form of an elemental selenium gas, or hydrogen selenide gas during the low pressure heating stage. In some embodiments, copper-indium-gallium oxide is deposited onto the back-electrode 104 and then converted to copper-indium-gallium diselenide. In some embodiments, a vacuum process is used to deposit absorber layer 106. In some embodiments, a non-vacuum process is used to deposit the absorber layer 106. In some embodiments, a room temperature process is used to deposit the absorber layer 106. In still other embodiments, a high temperature process is used to deposit the absorber layer 106. Those of skill in the art will appreciate that these processes are just exemplary and there are a wide range of other processes that can be used to deposit the absorber layer 106. In some embodiments, the absorber layer 106 is deposited using chemical vapor deposition.

Referring to FIGS. 3E and 3F, the window layer 108 is disposed on the absorber layer 106. In some embodiments, the absorber layer 106 is deposited onto the absorber layer 108 using a chemical bath deposition process. For instance, in the case where the window layer 108 is a buffer layer such as cadmium sulfide, the cadmium and sulfide can each be separately provided in solutions that, when reacted, results in cadmium sulfide precipitating out of the solution. Other compositions that can serve as window layer include, but are not limited to indium sulfide, zinc oxide, zinc oxide hydroxy sulfide or other types of buffer layers. In some embodiments, the window layer 108 is an n type buffer layer. In some embodiments, the window layer 108 is sputtered onto the absorber layer 106. In some embodiments, the window layer 108 is evaporated onto the absorber layer 106. In some embodiments, the window layer 108 is disposed onto the absorber layer 106 using chemical vapor deposition.

Referring to FIGS. 3G and 3H, the semiconductor junction 406 (e.g., layers 106 and 108) are patterned in order to create the grooves 294. In some embodiments, the grooves 294 run the full perimeter of the semiconductor junction 406, thereby breaking the semiconductor junction 406 into discrete sections. In some embodiments, the grooves 294 do not run the full perimeter of the semiconductor junction 406. In fact, in some embodiments, each groove only extends a small percentage of the perimeter of the semiconductor junction 406. In some embodiments, each solar cell 700 may have one, two, three, four or more, ten or more, or one hundred or more pockets arranged around the perimeter of the semiconductor junction 406 instead of a given groove 294. In some embodiments, the grooves 294 are scribed using a laser beam having a wavelength that is absorbed by semiconductor the junction 406. In some embodiments, the grooves 294 are scribed using mechanical means. For example, a razor blade or other sharp instrument is dragged over semiconductor the junction 406 thereby creating the grooves 294. In some embodiments, the grooves 294 are formed using a lithographic etching method.

Referring to FIG. 3I, the transparent conductive layer 110 is disposed on the semiconductor junction 406. In some embodiments, the transparent conductive layer 110 is deposited onto the back-electrode 104 by sputtering. In some embodiments, the sputtering is reactive sputtering. For example, in some embodiments a zinc target is used in the presence of oxygen gas to produce a transparent conductive layer 110 comprising zinc oxide. In another reactive sputtering example, an indium tin target is used in the presence of oxygen gas to produce a transparent conductive layer 110 comprising indium tin oxide. In another reactive sputtering example, a tin target is used in the presence of oxygen gas to produce a transparent conductive layer 110 comprising tin oxide. In general, any wide bandgap conductive transparent material can be used as the transparent conductive layer 110. As used herein, the term “transparent” means a material that is considered transparent in the wavelength range from about 300 nanometers to about 1500 nanometers. However, components that are not transparent across this full wavelength range can also serve as a transparent conductive layer 110, particularly if they have other properties such as high conductivity such that very thin layers of such materials can be used. In some embodiments, the transparent conductive layer 110 is any transparent conductive oxide that is conductive and can be deposited by sputtering, either reactively or using ceramic targets.

In some embodiments, the transparent conductive layer 110 is deposited using direct current (DC) diode sputtering, radio frequency (RF) diode sputtering, triode sputtering, DC magnetron sputtering or RF magnetron sputtering. In some embodiments, the transparent conductive layer 110 is deposited using atomic layer deposition. In some embodiments, the transparent conductive layer 110 is deposited using chemical vapor deposition.

Referring to 3J, the transparent conductive layer 110 is patterned in order to create the grooves 296. The grooves 296 run the full perimeter of the transparent conductive layer 110 thereby breaking the transparent conductive layer 110 into discrete sections. The bottoms of the grooves 296 expose the underlying semiconductor junction 406. In some embodiments, a groove 298 is patterned at an end of the solar cell unit 300 in order to connect the back-electrode 104 exposed by the groove 298 to an electrode or other electronic circuitry. In some embodiments, the grooves 296 are scribed using a laser beam having a wavelength that is absorbed by the transparent conductive layer 110. In some embodiments, the grooves 296 are scribed using mechanical means. For example, a razor blade or other sharp instrument is dragged over the back-electrode 104 thereby creating the grooves 296. In some embodiments the grooves 296 are formed using a lithographic etching method.

Referring to FIG. 3K, the optional antireflective coating 112 is disposed on the transparent conductive layer 110 using conventional deposition techniques. In some embodiments, the solar cell units 300 are encased in a transparent casing 310. More details on how elongated solar cells such as solar cell unit 300 can be encased in a transparent tubular case are described in copending U.S. patent application Ser. No. 11/378,847, filed Mar. 18, 2006. In some embodiments, an optional filler layer 330 is used to ensure that there are no pockets of air between the outer layers of solar cell unit 300 and the transparent casing 310.

In some embodiments, the optional electrode strips 420 are deposited on transparent conductive layer 110 using ink jet printing. Examples of conductive ink that can be used for such strips include, but are not limited to silver loaded or nickel loaded conductive ink. In some embodiments epoxies as well as anisotropic conductive adhesives can be used to construct the electrode strips 420. In typical embodiments such inks or epoxies are thermally cured in order to form the electrode strips 420. In some embodiments, such electrode strips are not present in the solar cell unit 300. In fact, a primary advantage of the use of the monolithic integrated designs is that voltage across the length of the solar cell unit 300 is increased because of the independent solar cells 700. Thus, current is decreased, thereby reducing the current requirements of individual solar cells 700. As a result, in many embodiments, there is no need for electrode strips 420.

In some embodiments, the grooves 292, 294, and 296 are not concentric as illustrated in FIG. 3. Rather, in some embodiments, such grooves are spiraled down the tubular (long) axis of the substrate 403. The monolithic integration strategy of FIG. 3 has the advantage of minimal area and a minimal number of process steps.

Referring to FIG. 3L, the optional filler layer 330 is disposed onto the transparent conductive layer 110 or the antireflective layer 112. Referring to FIG. 3M, depending on the embodiments, the transparent nonplanar casing 310 is fitted onto the optional filler layer 330 (if present), or antireflective layer 112 (if present and if optional filler layer 330 is not present) or the transparent conductive layer 110 (if optional filler layer 330 and antireflective layer 112 are not present).

### 5.1.2 Transparent Casing

A transparent casing 310, as depicted in FIGS. 2A and 2B, seals a solar cell unit 300 to provide support and protection to the solar cell. The size and dimensions of the transparent casing 310 are determined by the size and dimension of the individual solar cells 700 in a solar cell unit 300. Transparent casing 310 may be made of glass, plastic or any other suitable material. Examples of materials that can be used to make the transparent casing 310 include, but are not limited to, glass (e.g., soda lime glass), acrylics such as polymethylmethacrylate, polycarbonate, fluoropolymer (e.g., Tefzel or Teflon), polyethylene terephthalate (PET), Tedlar, or some other suitable transparent material.

Transparent tubular casing made of glass. In some embodiments, the transparent casing 310 is made of glass. A wide variety of glasses for transparent casing 310 are contemplated herein, some of which are described in this section and others of which are known to those of skill in the relevant arts. Common glass contains about 70% amorphous silicon dioxide (SiO₂), which is the same chemical compound found in quartz, and its polycrystalline form, sand. Common glass is used in some embodiments to make the transparent casing 310. However, common glass is brittle and will break into sharp shards. Thus, in some embodiments, the properties of common glass are modified, or even changed entirely, with the addition of other compounds or heat treatment.

Pure silica (SiO₂) has a melting point of about 2000° C., and can be made into glass for special applications (for example, fused quartz). Two other substances are always added to common glass to simplify processing. One is soda (sodium carbonate Na₂CO₃), or potash, the equivalent potassium compound, which lowers the melting point to about 1000° C. However, the soda makes the glass water-soluble, which is undesirable, so lime (calcium oxide, CaO) is the third component, added to restore insolubility. The resulting glass contains about 70% silica and is called a soda-lime glass. Soda-lime glass is used in some embodiments to make the transparent casing 310.

Besides soda-lime, most common glass has other ingredients added to change its properties. Lead glass, such as lead crystal or flint glass, is more ‘brilliant’ because the increased refractive index causes noticeably more “sparkles”, while boron may be added to change the thermal and electrical properties, as in Pyrex. Adding barium also increases the refractive index. Thorium oxide gives glass a high refractive index and low dispersion, and was formerly used in producing high-quality lenses, but due to its radioactivity has been replaced by lanthanum oxide in modern glasses. Large amounts of iron are used in glass that absorbs infrared energy, such as heat absorbing filters for movie projectors, while cerium(IV) oxide can be used for glass that absorbs UV wavelengths (biologically damaging ionizing radiation). Glass having on or more of any of these additives is used in some embodiments to make the transparent casing 310.

Common examples of glass material include but are not limited to aluminosilicate, borosilicate (e.g., Pyrex, Duran, Simax), dichroic, germanium/semiconductor, glass ceramic, silicate/fused silica, soda lime, quartz, chalcogenide/sulphide, cereated glass, and fluoride glass and the transparent casing 310 can be made of any of these materials.

In some embodiments, the transparent casing 310 is made of soda lime glass. Soda lime glass is softer than borosilicate and quartz, making scribe cutting easier and faster. Soda Lime glass is very low cost and easy to mass produce. However, Soda lime glass has poor thermal shock resistance. Thus, soda lime glass is best used for the transparent casing 310 in thermal environments where heating is very uniform and gradual. As a result, when the solar cells 700 are encased by the transparent casing 310 made from soda lime glass, such cells are best used in environments where temperature does not drastically fluctuate.

In some embodiments, the transparent casing 310 is made of glass material such as borosilicate glass. Trade names for borosilicate glass include but are not limited to Pyrex® (Corning), Duran® (Schott Glass), and Simax® (Kavalier). Like most glasses, the dominant component of borosilicate glass is SiO₂ with boron and various other elements added. Borosilicate glass is easier to hot work than materials such as quartz, making fabrication less costly. Material cost for borosilicate glass is also considerably less than fused quartz. Compared to most glass, except fused quartz, borosilicate glass has low coefficient of expansion, three times less than soda lime glass. This makes borosilicate glass useful in thermal environments, without the risk of breakage due to thermal shock. Like soda lime glass, a float process can be used to make relatively low cost optical quality sheet borosilicate glass in a variety of thickness from less than 1 mm to over 30 mm thick. Relative to quartz, borosilicate glass is easily moldable. In addition, borosilicate glass has minimum devitrification when molding and flame working. This means high quality surfaces can be maintained when molding and slumping. Borosilicate glass is thermally stable up to 500° C. for continuous use. Borosilicate glass is also more resistant to non-fluorinated chemicals than household soda lime glass and mechanically stronger and harder than soda lime glass. Borosilicate is usually two to three times more expensive than soda lime glass.

Soda lime and borosilicate glass are only given as examples to illustrate the various aspects of consideration when using glass material to fabricate the transparent casing 310. The preceding discussion imposes no limitation to the scope of the present disclosure. Indeed, the transparent nonplanar casing 310 can be made with glass such as, for example, aluminosilicate, borosilicate (e.g., PYRAX®, DURAN®, SIMAX®), dichroic, germanium/semiconductor, glass ceramic, silicate/fused silica, soda lime, quartz, chalcogenide/sulphide, cereated glass and/or fluoride glass.

Transparent tubular casing made of plastic. In some embodiments, the transparent casing 310 is made of clear plastic. Plastics are a cheaper alternative to glass. However, plastic material is in general less stable under heat, has less favorable optical properties and does not prevent molecular water from penetrating through the transparent casing 310. The last factor, if not rectified, damages the solar cells 700 and severely reduces their lifetime. Accordingly, in some embodiments, a water resistant layer described above is used to prevent water seepage into the solar cells 402 when the transparent casing 310 is made of plastic.

A wide variety of materials can be used in the production of the transparent casing 310, including, but not limited to, ethylene vinyl acetate (EVA), perfluoroalkoxy fluorocarbon (PFA), nylon/polyamide, cross-linked polyethylene (PEX), polyolefin, polypropylene (PP), polyethylene terephtalate glycol (PETG), polytetrafluoroethylene (PTFE), thermoplastic copolymer (for example, ETFE®, which is a derived from the polymerization of ethylene and tetrafluoroethylene: TEFLON® monomers), polyurethane/urethane, polyvinyl chloride (PVC), polyvinylidene fluoride (PVDF), Tygon®, Vinyl, and Viton®.

In order to maximize input of solar radiation, any layer outside a solar cell 700 (for example, the optional filler layer 330 or the transparent casing 310) preferably should not adversely affect the properties of incident radiation on the solar cell. There are multiple factors to consider in optimizing the efficiency of the solar cells 402. A few factors in relation to solar cell production are described below.

Transparency. In order to establish maximized input into solar cell absorption layer (e.g., the semiconductor junction 410), absorption of the incident radiation by any layer outside a solar cell 402 should be avoided or minimized. This transparency requirement varies as a function of the absorption properties of the underlying the semiconductor junction 410 of the solar cells 700. In general, the transparent casing 310 and the optional filler layer 330 are preferably as transparent as possible to the wavelengths absorbed by the semiconductor junction 410. For example, when the semiconductor junction 410 is based on CIGS, materials used to make the transparent casing 310 and the optional filer layer 330 are preferably transparent to light in the 500 nm to 1200 nm wavelength range.

Ultraviolet Stability. Any material used to construct a layer outside the solar cell 700 is preferably chemically stable and, in particular, stable upon exposure to UV radiation. More specifically, such material should not become less transparent upon UV exposure. Ordinary glass partially blocks UVA (wavelengths 400 and 300 nm) and it totally blocks UVC and UVB (wavelengths lower than 300 nm). The UV blocking effect of glass is usually due additives, e.g. sodium carbonate, in glass. In some embodiments, additives in the transparent casing 310 made of glass can render the casing 310 entirely UV protective. In such embodiments, because the transparent casing 310 provides complete protection from UV wavelengths, the UV stability requirements of the underlying optional filler layer 330 are reduced. For example, EVA, PVB, TPU (urethane), silicones, polycarbonates, and acrylics can be adapted to form a filler layer 330 when the transparent casing 310 is made of UV protective glass. Alternatively, in some embodiments, where the transparent casing 310 is made of plastic material, UV stability requirement is preferably adhered to.

Plastic materials that are sensitive to UV radiation are preferably not used as transparent casing 310 because yellowing of the material and/or optional filler layer 330 blocks radiation input into the solar cells 402 and reduces their efficiency. In addition, cracking of the transparent casing 310 due to UV exposure permanently damages the solar cells 402. For example, fluoropolymers like ETFE, and THV (Dyneon) are UV stable and highly transparent, while PET is transparent, but not sufficiently UV stable. In some embodiments, the transparent casing 310 is made of fluoropolymer based on monomers of tetrafluoroethylene, hexafluoropropylene and vinylidene fluoride. In addition, polyvinyl chloride (“PVC” or “vinyl”), one of the most common synthetic materials, is also sensitive to UV exposure. Methods have been developed to render PVC UV-stabilized, but even UV stabilized PVC is typically not sufficiently durable (for example, yellowing and cracking of PVC product will occur over relative short term usage). Urethanes are better suited, but depend on the exact chemical nature of the polymer backbone. Urethane material is stable when the polymer backbone is formed by less reactive chemical groups (e.g., aliphatic or aromatic). On the other hand when the polymer backbone is formed by more reactive groups (e.g., double bonds), yellowing of the material occurs as a result of UV-catalyzed breakdown of the double bonds. Similarly, EVA will yellow and so will PVB upon continued exposure to UV light. Other options are polycarbonate (can be stabilized against UV for up to 10 years OD exposure) or acrylics (inherently UV stable).

Reflective Properties. In order to maximize input of solar radiation, reflection at the outer surface of the transparent casing 310 should be minimized. Antireflective coating, either as a separate layer or in combination with the water resistant coating, may be applied on the outside of the transparent casing 310. In some embodiments, this antireflective coating is made of MgF₂. In some embodiments, this antireflective coating is made of silicone nitrate or titanium nitrate. In other embodiments, this antireflective coating is made of one or more layers of silicon monoxide (SiO). For example, shiny silicon can act as a mirror and reflects more than thirty percent of the light that shines on it. A single layer of SiO reduces surface reflection to about ten percent, and a second layer of SiO can lower the reflection to less than four percent. Other organic antireflective materials, in particular, one which prevents back reflection from the surface of or lower layers in the semiconductor device and eliminates the standing waves and reflective notching due to various optical properties of lower layers on the wafer and the photosensitive film, are disclosed in U.S. Pat. No. 6,803,172. Additional antireflective coating materials and methods are disclosed in U.S. Pat. Nos. 6,689,535; 6,673,713; 6,635,583; 6,784,094; and 6,713,234.

Alternatively, the outer surface of the transparent casing 310 may be textured to reduce reflected radiation. Chemical etching creates a pattern of cones and pyramids, which capture light rays that might otherwise be deflected away from the cell. Reflected light is redirected down into the cell, where it has another chance to be absorbed. Material and methods for creating an anti-reflective layer by etching or by a combination of etching and coating techniques are disclosed in U.S. Pat. Nos. 6,039,888; 6,004,722; and 6,221,776.

Refractive Properties. In some embodiments, refractive index of the filler layer 330 is larger than the refractive index of the transparent casing 310 so that light will also be bent towards the solar cell 402. In this situation, every incident beam on the transparent casing 310 will be bent towards the solar cell 402 after two reflection processes. In practice, however, the optional filler layer 330 is made of a fluid-like material (albeit sometimes very viscous fluid-like material) such that loading of the solar cells 402 into the transparent casing 310 may be achieved as described above. In practice, efficient solar radiation absorption is achieved by choosing filler material that has refractive index close to those of the transparent casing 310. In some embodiments, materials that form the transparent casing 310 comprise transparent materials (either glass or plastic or other suitable materials) with refractive indices around 1.5. For example, fused silica glass has a refractive index of 1.46. Borosilicate glass materials have refractive indices between 1.45 and 1.55 (e.g., Pyrex® glass has a refractive index of 1.47). Flint glass materials with various amounts of lead additive have refractive indices between 1.5 and 1.9. Common plastic materials have refractive indices between 1.46 and 1.55.

Exemplary materials with the appropriate optical properties for forming the filler layer 330 further comprise silicone, polydimethyl siloxane (PDMS), silicone gel, epoxy, and acrylic material. Because silicone-based adhesives and sealants have a high degree of flexibility, they lack the strength of other epoxy or acrylic resins. Transparent casing 310, optional filler layer 330, optional antireflective layer, water-resistant layer, or any combination thereof form a package to maximize and maintain solar cell efficiency, provide physical support, and prolong the life time of the solar cell units 700.

In some embodiments, glass, plastic, epoxy or acrylic resin may be used to form the transparent casing 310. In some embodiments, the optional antireflective layer and/or water resistant coating are disposed on the transparent casing 310. In some such embodiments, the filler layer 330 is formed by softer and more flexible optically suitable material such as silicone gel. For example, in some embodiments, the filler layer 330 is formed by a silicone gel such as a silicone-based adhesives or sealants. In some embodiments, the filler layer 330 is formed by GE RTV 615 Silicone. RTV 615 Silicone is an optically clear, two-part flowable silicone product that requires SS4120 as primer for polymerization. (RTV615-1P and SS4120 are both available from General Electric (Fairfield, Conn.). Silicone-based adhesives or sealants are based on tough silicone elastomeric technology.

Advantageously, silicone adhesives have a high degree of flexibility and very high temperature resistance (up to 600° F.). Silicone-based adhesives and sealants have a high degree of flexibility. Silicone-based adhesives and sealants are available in a number of technologies (or cure systems). These technologies include pressure sensitive, radiation cured, moisture cured, thermo-set and room temperature vulcanizing (RTV). In some embodiments, the silicone-based sealants use two-component addition or condensation curing systems or single component (RTV) forms. RTV forms cure easily through reaction with moisture in the air and give off acid fumes or other by-product vapors during curing.

Pressure sensitive silicone adhesives adhere to most surfaces with very slight pressure and retain their tackiness. This type of material forms viscoelastic bonds that are aggressively and permanently tacky, and adheres without the need of more than finger or hand pressure. In some embodiments, radiation is used to cure silicone-based adhesives. In some embodiments, ultraviolet light, visible light or electron bean irradiation is used to initiate curing of sealants, which allows a permanent bond without heating or excessive heat generation. While UV-based curing requires one substrate to be UV transparent, the electron beam can penetrate through material that is opaque to UV light. Certain silicone adhesives and cyanoacrylates based on a moisture or water curing mechanism may need additional reagents properly attached to the solar cell without affecting the proper functioning of the solar cells. Thermo-set silicone adhesives and silicone sealants are cross-linked polymeric resins cured using heat or heat and pressure. Cured thermo-set resins do not melt and flow when heated, but they may soften. Vulcanization is a thermosetting reaction involving the use of heat and/or pressure in conjunction with a vulcanizing agent, resulting in greatly increased strength, stability and elasticity in rubber-like materials. RTV silicone rubbers are room temperature vulcanizing materials. The vulcanizing agent is a cross-linking compound or catalyst. In some embodiments, sulfur is added as the traditional vulcanizing agent.

In some embodiments, for example, when the optional filler layer 330 is absent, epoxy or acrylic material may be applied directly over the solar cell 700 to form the transparent casing 310 directly. In such embodiments, care is taken to ensure that the non-glass transparent casing 310 is also equipped with water resistant and/or antireflective properties to ensure efficient operation over a reasonable period of usage time.

Electrical Insulation. An important characteristic of transparent casing 310 and optional filler layer 330 is that these layers should provide complete electrical insulation. No conductive material should be used to form either the transparent casing 310 or the optional filler layer 330.

Dimension requirement. The combined width of each of the layers outside the solar cell 402 (e.g., the combination of the transparent casing 310 and/or the optional filler layer 330) in some embodiments is:

$${r}_{i} \geq \frac{{r}_{o}}{{η}_{outer ring}}$$

where, referring to FIG. 3B,

rᵢ is the radius of the solar cell 402, assuming that the semiconductor junction 410 is a thin-film junction;

rₒ is the radius of the outermost layer of the transparent casing 310 and/or the optional filler layer 330; and

η_{outer ring} is the refractive index of the outermost layer of the transparent casing 310 and/or the optional filler layer 330. As noted above, the refractive index of many of the materials used to make the transparent casing 310 and/or optional filler layer 330 is about 1.5. Thus, in typical embodiments, values of rₒ are permissible that are less than 1.5*rᵢ. This constraint places a boundary on allowable thickness for the combination of the transparent casing 310 and/or the optional filler layer 330.

### 5.2 Exemplary Semiconductor Junctions

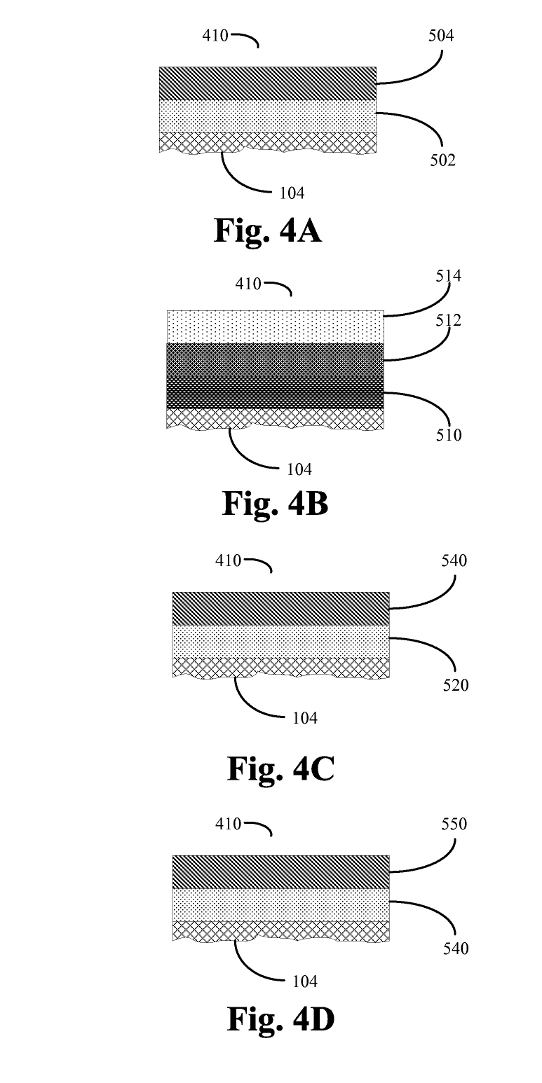

Referring to FIG. 4A, in one embodiment, the semiconductor junction 410 is a heterojunction between an absorber layer 502, disposed on a back-electrode 104, and a junction partner layer 504, disposed on the absorber layer 502. The absorber layer 502 and the junction partner layer 504 are composed of different semiconductors with different band gaps and electron affinities such that the junction partner layer 504 has a larger band gap than the absorber layer 502. In some embodiments, the absorber layer 502 is p-doped and the junction partner layer 504 is n-doped. In such embodiments, the transparent conductive layer 110 is n⁺-doped. In alternative embodiments, the absorber layer 502 is n-doped and the junction partner layer 504 is p-doped. In such embodiments, the transparent conductive layer 110 is p⁺-doped. In some embodiments, the semiconductors listed in Pandey, Handbook of Semiconductor Electrodeposition, Marcel Dekker Inc., 1996, Appendix 5, which is hereby incorporated by reference herein in its entirety, are used to form the semiconductor junction 410.

### 5.2.1 Thin-Film Semiconductor Junctions Based on Copper Indium Diselenide and Other Type I-III-VI Materials

Continuing to refer to FIG. 4A, in some embodiments, the absorber layer 502 is a group I-III-VI₂ compound such as copper indium di-selenide (CuInSe₂; also known as CIS). In some embodiments, the absorber layer 502 is a group I-III-VI₂ ternary compound selected from the group consisting of CdGeAs₂, ZnSnAs₂, CuInTe₂, AgInTe₂, CuInSe₂, CuGaTe₂, ZnGeAs₂, CdSnP₂, AgInSe₂, AgGaTe₂, CuInS₂, CdSiAs₂, ZnSnP₂, CdGeP₂, ZnSnAs₂, CuGaSe₂, AgGaSe₂, AgInS₂, ZnGeP₂, ZnSiAs₂, ZnSiP₂, CdSiP₂, or CuGaS₂ of either the p-type or the n-type when such compound is known to exist.

In some embodiments, the junction partner layer 504 is CdS, ZnS, ZnSe, or CdZnS. In one embodiment, the absorber layer 502 is p-type CIS and the junction partner layer 504 is n⁻ type CdS, ZnS, ZnSe, or CdZnS. Such semiconductor junctions 410 are described in Chapter 6 of Bube, Photovoltaic Materials, 1998, Imperial College Press, London, which is hereby incorporated by reference in its entirety.

In some embodiments, the absorber layer 502 is copper-indium-gallium-diselenide (CIGS). Such a layer is also known as Cu(InGa)Se₂. In some embodiments, the absorber layer 502 is copper-indium-gallium-diselenide (CIGS) and the junction partner layer 504 is CdS, ZnS, ZnSe, or CdZnS. In some embodiments, the absorber layer 502 is p-type CIGS and the junction partner layer 504 is n-type CdS, ZnS, ZnSe, or CdZnS. Such semiconductor junctions 410 are described in Chapter 13 of Handbook of Photovoltaic Science and Engineering, 2003, Luque and Hegedus (eds.), Wiley & Sons, West Sussex, England, Chapter 12, which is hereby incorporated by reference in its entirety. In some embodiments, CIGS is deposited using techniques disclosed in Beck and Britt, Final Technical Report, January 2006, NREL/SR-520-39119; and Delahoy and Chen, August 2005, “Advanced CIGS Photovoltaic Technology,” subcontract report; Kapur et al., January 2005 subcontract report, NREL/SR-520-37284, “Lab to Large Scale Transition for Non-Vacuum Thin Film CIGS Solar Cells”; Simpson et al., October 2005 subcontract report, “Trajectory-Oriented and Fault-Tolerant-Based Intelligent Process Control for Flexible CIGS PV Module Manufacturing,” NREL/SR-520-38681; and Ramanathan et al., 31^{st} IEEE Photovoltaics Specialists Conference and Exhibition, Lake Buena Vista, Fla., Jan. 3-7, 2005, each of which is hereby incorporated by reference herein in its entirety.

In some embodiments, the CIGS absorber layer 502 is grown on a molybdenum back-electrode 104 by evaporation from elemental sources in accordance with a three stage process described in Ramanthan et al., 2003, “Properties of 19.2% Efficiency ZnO/CdS/CuInGaSe₂ Thin-film Solar Cells,” Progress in Photovoltaics: Research and Applications 11, 225, which is hereby incorporated by reference herein in its entirety. In some embodiments, the junction partner layer 504 is a ZnS(O,OH) buffer layer as described, for example, in Ramanathan et al., Conference Paper, “CIGS Thin-Film Solar Research at NREL: FY04 Results and Accomplishments,” NREL/CP-520-37020, January 2005, which is hereby incorporated by reference herein in its entirety.

In some embodiments, the absorber layer 502 is between 0.5 μm and 2.0 μm thick. In some embodiments, the composition ratio of Cu/(In+Ga) in the absorber layer 502 is between 0.7 and 0.95. In some embodiments, the composition ratio of Ga/(In +Ga) in the absorber layer 502 is between 0.2 and 0.4. In some embodiments the CIGS absorber has a <110> crystallographic orientation. In some embodiments the CIGS absorber has a <112> crystallographic orientation. In some embodiments the CIGS absorber is randomly oriented.

### 5.2.2 Semiconductor Junctions Based on Amorphous Silicon or Polycrystalline Silicon

In some embodiments, referring to FIG. 4B, the semiconductor junction 410 comprises amorphous silicon. In some embodiments this is an n/n type heterojunction. For example, in some embodiments, layer 514 comprises SnO₂(Sb), layer 512 comprises undoped amorphous silicon, and layer 510 comprises n+ doped amorphous silicon.

In some embodiments, the semiconductor junction 410 is a p-i-n type junction. For example, in some embodiments, layer 514 is p⁺ doped amorphous silicon, layer 512 is undoped amorphous silicon, and layer 510 is n⁺ amorphous silicon. Such semiconductor junctions 410 are described in Chapter 3 of Bube, Photovoltaic Materials, 1998, Imperial College Press, London, which is hereby incorporated by reference in its entirety.

In some embodiments, the semiconductor junction 410 is based upon thin-film polycrystalline. Referring to FIG. 4B, in one example in accordance with such embodiments, layer 510 is a p-doped polycrystalline silicon, layer 512 is depleted polycrystalline silicon and layer 514 is n-doped polycrystalline silicon. Such semiconductor junctions are described in Green, Silicon Solar Cells: Advanced Principles & Practice, Centre for Photovoltaic Devices and Systems, University of New South Wales, Sydney, 1995; and Bube, Photovoltaic Materials, 1998, Imperial College Press, London, pp. 57-66, which is hereby incorporated by reference in its entirety.

In some embodiments, semiconductor junctions 410 based upon p-type microcrystalline Si:H and microcrystalline Si:C:H in an amorphous Si:H solar cell are used. Such semiconductor junctions are described in Bube, Photovoltaic Materials, 1998, Imperial College Press, London, pp. 66-67, and the references cited therein, which is hereby incorporated by reference in its entirety.

In some embodiments, the semiconductor junction 410 is a tandem junction. Tandem junctions are described in, for example, Kim et al., 1989, “Lightweight (AlGaAs)GaAs/CuInSe2 tandem junction solar cells for space applications,” Aerospace and Electronic Systems Magazine, IEEE 4: 23-32; Deng, 2005, “Optimization of a-SiGe based triple, tandem and single junction solar cells,” Photovoltaic Specialists Conference, 2005 Conference Record of the Thirty-first IEEE 3-7 Jan. 2005 Pages: 1365-1370; Arya et al., 2000, Amorphous silicon based tandem junction thin-film technology: a manufacturing perspective,” Photovoltaic Specialists Conference, 2000. Conference Record of the Twenty-Eighth IEEE 15-22 Sep. 2000 Pages: 1433-1436; Hart, 1988, “High altitude current-voltage measurement of GaAs/Ge solar cells,” Photovoltaic Specialists Conference, 1988, Conference Record of the Twentieth IEEE 26-30 Sep. 1988 Pages: 764-765 vol. 1; Kim, 1988, “High efficiency GaAs/CuInSe2 tandem junction solar cells,” Photovoltaic Specialists Conference, 1988, Conference Record of the Twentieth IEEE 26-30 Sep. 1988 Pages: 457-461 vol. 1; Mitchell, 1988, “Single and tandem junction CuInSe2 cell and module technology,” Photovoltaic Specialists Conference, 1988, Conference Record of the Twentieth IEEE 26-30 September 1988 Pages: 1384-1389 vol. 2; and Kim, 1989, “High specific power (AlGaAs)GaAs/CuInSe2 tandem junction solar cells for space applications,” Energy Conversion Engineering Conference, 1989, IECEC-89, Proceedings of the 24^{th} Intersociety 6-11 Aug. 1989 Pages: 779-784 vol. 2, each of which is hereby incorporated by reference herein in its entirety.

### 5.2.3 Semiconductor Junctions Based on Gallium Arsenide and Other Type III-V Materials

In some embodiments, semiconductor junctions 410 are based upon gallium arsenide (GaAs) or other III-V materials such as InP, AlSb, and CdTe. GaAs is a direct-band gap material having a band gap of 1.43 eV and can absorb 97% of AM1 radiation in a thickness of about two microns. Suitable type III-V junctions that can serve as semiconductor junctions 410 are described in Chapter 4 of Bube, Photovoltaic Materials, 1998, Imperial College Press, London, which is hereby incorporated by reference in its entirety.

Furthermore, in some embodiments, the semiconductor junction 410 is a hybrid multijunction solar cell such as a GaAs/Si mechanically stacked multijunction as described by Gee and Virshup, 1988, 20^{th} IEEE Photovoltaic Specialist Conference, IEEE Publishing, New York, p. 754, which is hereby incorporated by reference herein in its entirety, a GaAs/CuInSe₂ MSMJ four-terminal device, consisting of a GaAs thin film top cell and a ZnCdS/CuInSe₂ thin bottom cell described by Stanbery et al., 19^{th} IEEE Photovoltaic Specialist Conference, IEEE Publishing, New York, p. 280, and Kim et al., 20^{th} IEEE Photovoltaic Specialist Conference, IEEE Publishing, New York, p. 1487, each of which is hereby incorporated by reference herein in its entirety. Other hybrid multijunction solar cells are described in Bube, Photovoltaic Materials, 1998, Imperial College Press, London, pp. 131-132, which is hereby incorporated by reference herein in its entirety.

### 5.2.4 Semiconductor Junctions Based on Cadmium Telluride and Other Type II-VI Materials

In some embodiments, the semiconductor junctions 410 are based upon II-VI compounds that can be prepared in either the n-type or the p-type form. Accordingly, in some embodiments, referring to FIG. 4C, the semiconductor junction 410 is a p-n heterojunction in which the layers 520 and 540 are any combination set forth in the following table or alloys thereof

| Layer 520 | Layer 540 |
|---|---|
| n-CdSe | p-CdTe |
| n-ZnCdS | p-CdTe |
| n-ZnSSe | p-CdTe |
| p-ZnTe | n-CdSe |
| n-CdS | p-CdTe |
| n-CdS | p-ZnTe |
| p-ZnTe | n-CdTe |
| n-ZnSe | p-CdTe |
| n-ZnSe | p-ZnTe |
| n-ZnS | p-CdTe |
| n-ZnS | p-ZnTe |

Methods for manufacturing the semiconductor junctions 410 based upon II-VI compounds are described in Chapter 4 of Bube, Photovoltaic Materials, 1998, Imperial College Press, London, which is hereby incorporated by reference herein in its entirety.

### 5.2.5 Semiconductor Junctions Based on Crystalline Silicon

While the semiconductor junctions 410 that are made from thin film semiconductor films are preferred, the present disclosure is not so limited. In some embodiments the semiconductor junctions 410 is based upon crystalline silicon. For example, referring to FIG. 2B, in some embodiments, the semiconductor junction 410 comprises a layer of p-type crystalline silicon and a layer of n-type crystalline silicon. Methods for manufacturing crystalline silicon semiconductor junctions 410 are described in Chapter 2 of Bube, Photovoltaic Materials, 1998, Imperial College Press, London, which is hereby incorporated by reference herein in its entirety.

### 5.3 Albedo Embodiments

The solar cell designs disclosed herein are advantageous because they can collect light through the entire surface. Accordingly, in some embodiments, these solar cells are arranged in a reflective environment in which surfaces around the solar cell have some amount of albedo. Albedo is a measure of reflectivity of a surface or body. It is the ratio of electromagnetic radiation (EM radiation) reflected to the amount incident upon it. This fraction is usually expressed as a percentage from 0% to 100%. In some embodiments, surfaces in the vicinity of the disclosed solar cells are prepared so that they have a high albedo by painting such surfaces a reflective white color. In some embodiments, other materials that have a high albedo can be used. For example, the albedo of some materials around such solar cells approach or exceed ninety percent. See, for example, Boer, 1977, Solar Energy 19, 525, which is hereby incorporated by reference herein in its entirety. However, surfaces having any amount of albedo (e.g., five percent or more, ten percent or more, twenty percent or more) are within the scope of the present disclosure. In one embodiment, the solar cells units disclosed herein are arranged in rows above a gravel surface, where the gravel has been painted white in order to improve the reflective properties of the gravel. In general, any Lambertian or diffuse reflector surface can be used to provide a high albedo surface.

### 5.4 Dual Layer Core Embodiments

Embodiments in which the conductive core 104 of the solar cells 700 of the disclosed solar cell units is made of a uniform conductive material have been disclosed. The present disclosure is not limited to these embodiments. In some embodiments, the conductive core 104 in fact has an inner core and an outer conductive core. The inner core can be referred to as a substrate 403 while the outer core can be referred to as a back-electrode 104 in such embodiment. In such embodiments, the outer conductive core is disposed on the substrate 403. In such embodiments, the substrate 403 is typically nonconductive whereas the outer core is conductive. Substrate 403 has an elongated shape consistent with other embodiments disclosed herein. For instance, in one embodiment, the substrate 403 is made of glass fibers in the form of a wire. In some embodiments, the substrate 403 is an electrically conductive nonmetallic material. However, the disclosed apparatus are not limited to embodiments in which the substrate 403 is electrically conductive because the outer core can function as the electrode. In some embodiments, the substrate 403 is tubing (e.g., plastic or glass tubing).

In some embodiments, the substrate 403 is made of a material such as polybenzamidazole (e.g., CELAZOLE®, available from Boedeker Plastics, Inc., Shiner, Tex.). In some embodiments, the inner core is made of polymide (e.g., DUPONT®VESPEL®, or DUPONT®KAPTON®, Wilmington, Del.). In some embodiments, the inner core is made of polytetrafluoroethylene (PTFE) or polyetheretherketone (PEEK), each of which is available from Boedeker Plastics, Inc. In some embodiments, the substrate 403 is made of polyamide-imide (e.g., TORLON® PAI, Solvay Advanced Polymers, Alpharetta, Ga.).

In some embodiments, the substrate 403 is made of a glass-based phenolic. Phenolic laminates are made by applying heat and pressure to layers of paper, canvas, linen or glass cloth impregnated with synthetic thermosetting resins. When heat and pressure are applied to the layers, a chemical reaction (polymerization) transforms the separate layers into a single laminated material with a “set” shape that cannot be softened again. Therefore, these materials are called “thermosets.” A variety of resin types and cloth materials can be used to manufacture thermoset laminates with a range of mechanical, thermal, and electrical properties. In some embodiments, the substrate 403 is a phenoloic laminate having a NEMA grade of G-3, G-5, G-7, G-9, G-10 or G-11. Exemplary phenolic laminates are available from Boedeker Plastics, Inc.

In some embodiments, the substrate 403 is made of polystyrene. Examples of polystyrene include general purpose polystyrene and high impact polystyrene as detailed in Marks' Standard Handbook for Mechanical Engineers, ninth edition, 1987, McGraw-Hill, Inc., p. 6-174, which is hereby incorporated by reference herein in its entirety. In still other embodiments, the substrate 403 is made of cross-linked polystyrene. One example of cross-linked polystyrene is REXOLITE® (C-Lec Plastics, Inc). REXOLITE is a thermoset, in particular a rigid and translucent plastic produced by cross linking polystyrene with divinylbenzene.

In some embodiments, the substrate 403 is a polyester wire (e.g., a MYLAR® wire). MYLAR® is available from DuPont Teijin Films (Wilmington, Del.). In still other embodiments, the substrate 403 is made of DURASTONE®, which is made by using polyester, vinylester, epoxid and modified epoxy resins combined with glass fibers (Roechling Engineering Plastic Pte Ltd., Singapore).

In still other embodiments, the substrate 403 is made of polycarbonate. Such polycarbonates can have varying amounts of glass fibers (e.g., 10%, 20%, 30%, or 40%) in order to adjust tensile strength, stiffness, compressive strength, as well as the thermal expansion coefficient of the material. Exemplary polycarbonates are ZELUX® M and ZELUX® W, which are available from Boedeker Plastics, Inc.

In some embodiments, the substrate 403 is made of polyethylene. In some embodiments, the substrate 403 is made of low density polyethylene (LDPE), high density polyethylene (HDPE), or ultra high molecular weight polyethylene (UHMW PE). Chemical properties of HDPE are described in Marks' Standard Handbook for Mechanical Engineers, ninth edition, 1987, McGraw-Hill, Inc., p. 6-173, which is hereby incorporated by reference herein in its entirety. In some embodiments, the substrate 403 is made of acrylonitrile-butadiene-styrene, polytetrifluoro-ethylene (Teflon), polymethacrylate (lucite or plexiglass), nylon 6,6, cellulose acetate butyrate, cellulose acetate, rigid vinyl, plasticized vinyl, or polypropylene. Chemical properties of these materials are described in Marks' Standard Handbook for Mechanical Engineers, ninth edition, 1987, McGraw-Hill, Inc., pp. 6-172 through 6-175, which is hereby incorporated by reference herein in its entirety.

Additional exemplary materials that can be used to form the substrate 403 are found in Modern Plastics Encyclopedia, McGraw-Hill; Reinhold Plastics Applications Series, Reinhold Roff, Fibres, Plastics and Rubbers, Butterworth; Lee and Neville, Epoxy Resins, McGraw-Hill; Bilmetyer, Textbook of Polymer Science, Interscience; Schmidt and Marlies, Principles of high polymer theory and practice, McGraw-Hill; Beadle (ed.), Plastics, Morgan-Grampiand, Ltd., 2 vols. 1970; Tobolsky and Mark (eds.), Polymer Science and Materials, Wiley, 1971; Glanville, The Plastics's Engineer's Data Book, Industrial Press, 1971; Mohr (editor and senior author), Oleesky, Shook, and Meyers, SPI Handbook of Technology and Engineering of Reinforced Plastics Composites, Van Nostrand Reinhold, 1973, each of which is hereby incorporated by reference herein in its entirety.

In general, outer core is made out of any material that can support the photovoltaic current generated by solar cell with negligible resistive losses. In some embodiments, the outer core is made of any conductive metal, such as aluminum, molybdenum, steel, nickel, silver, gold, or an alloy thereof. In some embodiments, the outer core is made out of a metal-, graphite-, carbon black-, or superconductive carbon black-filled oxide, epoxy, glass, or plastic. In some embodiments, the outer core is made of a conductive plastic. In some embodiments, this conductive plastic is inherently conductive without any requirement for a filler. In some embodiments, the inner core is made out of a conductive material and the outer core is made out of molybdenum. In some embodiments, the inner core is made out of a nonconductive material, such as a glass rod, and the outer core is made out of molybdenum.

### 5.5 Exemplary Dimensions

Disclosed are solar cell units having any dimensions that fall within a broad range of dimensions. For example, the present disclosure encompasses solar cell units having a length/between 1 cm and 50,000 cm and a diameter w between 1 cm and 50,000 cm. In some embodiments, the solar cell units have a length/between 10 cm and 1,000 cm and a diameter w between 10 cm and 1,000 cm. In some embodiments, the solar cell units have a length/between 40 cm and 500 cm and a width w between 40 cm and 500 cm.

### 5.6 Additional Solar Cell Embodiments

Using FIG. 3B for reference to element numbers, in some embodiments, copper-indium-gallium-diselenide (Cu(InGa)Se₂), referred to herein as CIGS, is used to make the absorber layer of junction 110. In such embodiments, the back-electrode 104 can be made of molybdenum. In some embodiments, the back-electrode 104 comprises an inner core of polyimide and an outer core that is a thin film of molybdenum sputtered onto the polyimide core prior to CIGS deposition. On top of the molybdenum, the CIGS film, which absorbs the light, is evaporated. Cadmium sulfide (CdS) is then deposited on the CIGS in order to complete the semiconductor junction 410. Optionally, a thin intrinsic layer (i-layer) 415 is then deposited on the semiconductor junction 410. The i-layer 415 can be formed using a material including but not limited to, zinc oxide, metal oxide or any transparent material that is highly insulating. Next, the transparent conductive layer 110 is disposed on either the i-layer (when present) or the semiconductor junction 410 (when the i-layer is not present). The transparent conductive layer 110 can be made of a material such as aluminum doped zinc oxide (ZnO:Al), gallium doped zinc oxide, boron dope zinc oxide, indium-zinc oxide, or indium-tin oxide.

ITN Energy Systems, Inc., Global Solar Energy, Inc., and the Institute of Energy Conversion (IEC), have collaboratively developed technology for manufacturing CIGS photovoltaics on polyimide substrates using a roll-to-roll co-evaporation process for deposition of the CIGS layer. In this process, a roll of molybdenum-coated polyimide film (referred to as the web) is unrolled and moved continuously into and through one or more deposition zones. In the deposition zones, the web is heated to temperatures of up to ˜450° C. and copper, indium, and gallium are evaporated onto it in the presence of selenium vapor. After passing out of the deposition zone(s), the web cools and is wound onto a take-up spool. See, for example, 2003, Jensen et al., “Back Contact Cracking During Fabrication of CIGS Solar Cells on Polyimide Substrates,” NCPV and Solar Program Review Meeting 2003, NREL/CD-520-33586, pages 877-881, which is hereby incorporated by reference in its entirety. Likewise, Birkmire et al., 2005, Progress in Photovoltaics: Research and Applications 13, 141-148, hereby incorporated by reference, disclose a polyimide/Mo web structure, specifically, PI/Mo/Cu(InGa)Se₂/CdS/ZnO/ITO/Ni—Al. Deposition of similar structures on stainless foil has also been explored. See, for example, Simpson et al., 2004, “Manufacturing Process Advancements for Flexible CIGS PV on Stainless Foil,” DOE Solar Energy Technologies Program Review Meeting, PV Manufacturing Research and Development, P032, which is hereby incorporated by reference herein in its entirety.

In some embodiments, an absorber material is deposited onto a polyimide/molybdenum web, such as those developed by Global Solar Energy (Tucson, Ariz.), or a metal foil (e.g., the foil disclosed in Simpson et al.). In some embodiments, the absorber material is any of the absorbers disclosed herein. In a particular embodiment, the absorber is Cu(InGa)Se₂. In some embodiments, the elongated core is made of a nonconductive material such as undoped plastic. In some embodiments, the elongated core is made of a conductive material such as a conductive metal, a metal-filled epoxy, glass, or resin, or a conductive plastic (e.g., a plastic containing a conducting filler). Next, the semiconductor junction 410 is completed by depositing a window layer onto the absorber layer. In the case where the absorber layer is Cu(InGa)Se₂, CdS can be used. Finally, the optional i-layer 415 and the transparent conductive layer 110 are added to complete the solar cell. Next, the foil is wrapped around and/or glued to a wire-shaped or tube-shaped elongated core. The advantage of such a fabrication method is that material that cannot withstand the deposition temperature of the absorber layer, window layer, i-layer or the transparent conductive layer 110 can be used as an inner core for the solar cell. This manufacturing process can be used to manufacture any of the solar cells 402 disclosed herein, where the conductive core 402 comprises an inner core and an outer conductive core. The inner core is any conductive or nonconductive material disclosed herein whereas the outer conductive core is the web or foil onto which the absorber layer, window layer, and transparent conductive layer were deposited prior to rolling the foil onto the inner core. In some embodiments, the web or foil is glued onto the inner core using appropriate glue.

One embodiment provides a method of manufacturing a solar cell comprising depositing an absorber layer on a first face of a metallic web or a conducting foil. Next, a window layer is deposited on to the absorber layer. Next, a transparent conductive layer is deposited on to the window layer. The metallic web or conducting foil is then rolled around an elongated core, thereby forming an elongated solar cell 402. In some embodiments, the absorber layer is copper-indium-gallium-diselenide (Cu(InGa)Se₂) and the window layer is cadmium sulfide. In some embodiments, the metallic web is a polyimide/molybdenum web. In some embodiments, the conducting foil is steel foil or aluminum foil. In some embodiments, the elongated core is made of a conductive metal, a metal-filled epoxy, a metal-filled glass, a metal-filled resin, or a conductive plastic.

In some embodiments, a transparent conducting oxide conductive film is deposited on a tubular shaped or rigid solid rod shaped core rather than wrapping a metal web or foil around the elongated core. In such embodiments, the tubular shaped or rigid solid rod shaped core can be, for example, a plastic rod, a glass rod, a glass tube, or a plastic tube. Such embodiments require some form of conductor in electrical communication with the interior face or back contact of the semiconductor junction. In some embodiments, divots in the tubular shaped or rigid solid rod shaped elongated core are filled with a conductive metal in order to provide such a conductor. The conductor can be inserted in the divots prior to depositing the transparent conductive layer or conductive back contact film onto the tubular shaped or rigid solid rod shaped elongated core. In some embodiments, such a conductor is formed from a metal source that runs lengthwise along the side of the elongated solar cell 402. This metal can be deposited by evaporation, sputtering, screen printing, inkjet printing, metal pressing, conductive ink or glue used to attach a metal wire, or other means of metal deposition.

More specific embodiments will now be disclosed. In some embodiments, the elongated core is a glass tubing having a divot that runs lengthwise on the outer surface of the glass tubing, and the manufacturing method comprises depositing a conductor in the divot prior to the rolling step. In some embodiments, the glass tubing has a second divot that runs lengthwise on the surface of the glass tubing. In such embodiments, the first divot and the second divot are on approximate or exact opposite circumferential sides of the glass tubing. In such embodiments, accordingly, the method further comprises depositing a conductor in the second divot prior to the rolling or, in embodiments in which rolling is not used, prior to the deposition of an inner transparent conductive layer or conductive film, junction, and outer transparent conductive layer onto the elongated core.

In some embodiments, the elongated core is a glass rod having a first divot that runs lengthwise on the surface of the glass rod and the method comprises depositing a conductor in the first divot prior to the rolling. In some embodiments, the glass rod has a second divot that runs lengthwise on the surface of the glass rod and the first divot and the second divot are on approximate or exact opposite circumferential sides of the glass rod. In such embodiments, accordingly, the method further comprises depositing a conductor in the second divot prior to the rolling or, in embodiments in which rolling is not used, prior to the deposition of an inner transparent conductive layer or conductive film, junction, and outer transparent conductive layer onto the elongated core. Suitable materials for the conductor are any of the materials described as a conductor herein including, but not limited to, aluminum, molybdenum, titanium, steel, nickel, silver, gold, or an alloy thereof.

Another embodiment provides a solar cell assembly comprising a plurality of solar cell units 300, each solar cell unit in the plurality of solar cell units having the structure of any of the solar cell units illustrated in any of the embodiments described above. In some embodiments, the solar cell units in the plurality of solar cell units are arranged in coplanar rows to form the solar cell assembly. In some embodiments, there is an albedo surface positioned to reflect sunlight into the plurality of solar cell units. For instance, any of the self-cleaning albedo surfaces in U.S. patent application Ser. No. 11/315,523, which is hereby incorporated by reference herein in its entirety, can be used. In some embodiments, the albedo surface has an albedo that exceeds 40%, 50%, 60%, 70%, or 80%. In some embodiments, a first solar cell unit 300 and a second solar cell unit 300 in the plurality of solar cell units is electrically arranged in series. In some embodiments, a first solar cell unit 300 and a second solar cell unit 300 in the plurality of solar cell units is electrically arranged in parallel.

One aspect disclosed herein provides a solar cell assembly comprising a plurality of solar cell units 300, each solar cell unit in the plurality of solar cell units having the structure of any of the solar cell units described above. This aspect further comprises a plurality of internal reflectors. For instance any internal reflector, or combination of internal reflectors described in U.S. patent application Ser. No. 11/248,789, which is hereby incorporated by reference herein, can be used. The plurality of solar cell units and the plurality of internal reflectors are arranged in coplanar rows in which internal reflectors in the plurality of solar cell units abut solar cell units in the plurality of solar cell units thereby forming the solar cell assembly.

Unless otherwise indicated, the term “%” hereinafter means “% by weight” based on the total amount of glass. The expression “X is contained in an amount of from 0 to Y %” means that X is either not present, or is higher than 0% and not more than Y %. In some embodiments, substrate 403 and/or transparent casing 310 is made preferably from 40 to 70%, more preferably is from 45 to 70%, and still more preferably is from 50 to 65% SiO₂. In some embodiments, where the content of SiO₂ is not higher than 70%, it is suitable for mass production since the material melts easily. On the other hand, when the content of SiO₂ in substrate 403 and/or transparent casing 310 is not lower than 40%, the resulting glass maintains a superior chemical durability. In some embodiments, substrate 403 and/or transparent casing 310 is made of a glass that includes B₂O₃. B₂O₃ is a component that improves the meltability of glass, lowers the sealing temperature of glass, and enhances the chemical durability of glass. The content of B₂O₃ in some embodiments is 5 to 20%, more preferably is from 8 to 15%, and still more preferably is from 10 to 15%. When the content of B₂O₃ is not higher than 20%, the evaporation of B₂O₃ from the molten glass can be suppressed, thereby making it possible to obtain homogeneous glass. In some embodiments, the substrate 403 and/or the transparent casing 310 is made of a glass that includes Al₂O₃. Al₂O₃ is a component for improving the chemical durability of glass. The content of Al₂O₃ in some embodiments disclosed herein is preferably from 0 to 15%, and more preferably is from 0.5 to 10%. In some embodiments the substrate 403 and/or transparent casing 310 is made of glass that includes MgO, CaO, SrO, BaO and/or ZnO. These components have the effect of enhancing the chemical durability of the glass. The total content of MgO, CaO, SrO, BaO and ZnO in substrate 403 and/or the transparent casing 310 is preferably from 0 to 45%, more preferably is from 0 to 25%, still more preferably is from 1 to 25%, still further more preferably is from 1 to 20%, and most preferably is from 5 to 20%. When the total content of these components is not higher than 45%, it is possible to obtain a glass having a high homogeneity. In some embodiments the substrate 403 and/or the transparent casing 310 is made of a glass that includes at least two of Li₂O, Na₂O or K₂O, which are oxides of alkaline metal, in admixture to improve weathering resistance and electrical insulation of the glass. The total content of these oxides of alkaline metal is preferably from 5 to 25%, more preferably is from 10 to 25%, and still more preferably is from 14 to 20% in substrate 403 and/or the transparent casing 310 in some embodiments disclosed herein. When the total content of these oxides of alkaline metal is not higher than 25%, the resulting glass maintains chemical durability. On the other hand, when the total content of these oxides of alkaline metal is not lower than 5%, a low sealing temperature can be attained. The contents of Li₂O, Na₂O and K₂O are preferably from 0 to 10%, from 0 to 10% and from 0 to 15%, respectively, and more preferably are from 0.5 to 9%, from 0 to 9% and from 1 to 10%, respectively in some substrates 403 and/or transparent casings 310 in accordance with the present disclosure. When the content of each Li₂O and Na₂O independently, is not higher than 10% and the content of K₂O is not higher than 15%, the mixing effect of alkalis is effective, thereby maintaining a superior weathering resistance and high electrical insulation. Li₂O has the highest effect of lowering the sealing temperature of glass. Thus, the content of Li₂O is preferably not lower than 0.5%, particularly not lower than 3%. In addition to the foregoing components, components such as ZrO₂, TiO₂, P₂O₅, Fe₂O₃, SO₃, Sb₂O₃, F, and Cl, may be added to the glass composition of the substrate 403 and/or transparent casing 310 to improving the weathering resistance, meltability, and refining, of the glass.

### 6. REFERENCES CITED

All references cited herein are incorporated herein by reference in their entirety and for all purposes to the same extent as if each individual publication or patent or patent application was specifically and individually indicated to be incorporated by reference in its entirety for all purposes.

Many modifications and variations of the disclosed apparatus and methods can be made without departing from its spirit and scope, as will be apparent to those skilled in the art. The specific embodiments described herein are offered by way of example only, and the invention is to be limited only by the terms of the appended claims, along with the full scope of equivalents to which such claims are entitled.

What is claimed:

1. An elongated solar cell unit comprising:
(A) a substrate;
(B) one or more solar cells disposed on the substrate;
(C) a transparent casing disposed onto the one or more solar cells, the transparent nonplanar casing having a first end and a second end; and
(D) a first sealant cap that is hermetically sealed to the first end of the transparent nonplanar casing.

2. The elongated solar cell unit of claim 1, the elongated solar cell unit further comprising a second sealant cap that is hermetically sealed to the second end of the transparent casing.

3. The elongated solar cell unit of claim 1, wherein the first sealant cap is made of metal, metal alloy, or glass.

4. The elongated solar cell unit of claim 1, wherein the first sealant cap is hermetically sealed to an inner surface or an outer surface of said transparent casing.

5. The elongated solar cell unit of claim 1, wherein the transparent casing is made of borosilicate glass and the first sealant cap is made of KOVAR.

6. The elongated solar cell unit of claim 1, wherein the transparent casing is made of soda lime glass and the first sealant cap is made of a low expansion stainless steel alloy.

7. The elongated solar cell unit of claim 1, wherein the first sealant cap is hermetically sealed to an inner surface or an outer surface of said transparent casing, and wherein said hermetic seal is formed by a continuous strip of sealant.

8. The elongated solar cell unit of claim 7, wherein the continuous strip of sealant is on an inner edge of the first sealant cap, on an outer edge of the first sealant cap, on an outer edge of the transparent casing, or on an inner edge of the transparent casing.

9. The elongated solar cell unit of claim 7, wherein the continuous strip of sealant is formed from glass frit, sol-gel, or ceramic cement.

10. The elongated solar cell unit of claim 1, wherein each solar cell in the one or more solar cells comprises:
a back-electrode disposed on the substrate;
a semiconductor junction disposed on the back-electrode; and
a transparent conductive layer disposed on the semiconductor junction; and
wherein the first sealant cap is in electrical contact with said back-electrode of a first solar cell in the one or more solar cells and wherein said first sealant cap serves as an electrode for said back-electrode.

11. The elongated solar cell unit of claim 1, wherein each solar cell in the one or more solar cells comprises:
a back-electrode disposed on the substrate;
a semiconductor junction disposed on the back-electrode; and
a transparent conductive layer disposed on the semiconductor junction; and
wherein the first sealant cap is in electrical contact with said transparent conductive layer of a first solar cell in the one or more solar cells and wherein said first sealant cap serves as an electrode for said transparent conductive layer.

12. The elongated solar cell unit of claim 1, wherein a solar cell in the one or more solar cells comprises:
a back-electrode disposed on the substrate;
a semiconductor junction disposed on the back-electrode; and
a transparent conductive layer disposed on the semiconductor junction; wherein the semiconductor junction comprises a homojunction, a heterojunction, a heteroface junction, a buried homojunction, a p-i-n junction, or a tandem junction.

13. The elongated solar cell unit of claim 1, further comprising a filler layer disposed on said one or more solar cells, thereby sealing said one or more solar cells.

14. The elongated solar cell unit of claim 13, wherein the filler layer comprises ethylene vinyl acetate (EVA), silicone, silicone gel, epoxy, polydimethyl siloxane (PDMS), RTV silicone rubber, polyvinyl butyral (PVB), thermoplastic polyurethane (TPU), a polycarbonate, an acrylic, a fluoropolymer, or a urethane.

15. The elongated solar cell unit of claim 1, further comprising a water resistant layer disposed on said one or more solar cells thereby sealing said one or more solar cells.

16. The elongated solar cell unit of claim 15, wherein the water resistant layer comprises clear silicone, SiN, SiOₓN_{y}, SiOₓ, or Al₂O₃, wherein x and y are positive integers.

17. The elongated solar cell unit of claim 1, further comprising:
a water resistant layer disposed on said one or more solar cells; and
a filler layer disposed on said water resistant layer, wherein said transparent casing is disposed on said filler layer thereby sealing said one or more solar cells.

18. The elongated solar cell unit of claim 1, further comprising:
a filler layer disposed on said transparent conductive layer; and
a water resistant layer disposed on said water resistant layer, wherein said transparent casing is disposed on said water resistant layer thereby sealing said one or more solar cells.

19. The elongated solar cell unit of claim 1, further comprising an antireflective coating disposed on said transparent casing.

20. The elongated solar cell unit of claim 1, wherein the water vapor transmission rate of the solar cell unit is 10⁻⁴ g/m²·day or less.

21. The elongated solar cell unit of claim 1, wherein the water vapor transmission rate of the solar cell unit is 10⁻⁵ g/m²·day or less.

22. The elongated solar cell unit of claim 1, wherein the water vapor transmission rate of the solar cell unit is 10⁻⁶ g/m²·day or less.

23. The elongated solar cell unit of claim 1, wherein the water vapor transmission rate of the solar cell unit is 10⁻⁷ g/m²·day or less.

24. The elongated solar cell unit of claim 1, wherein the elongated solar cell unit has at least one width dimension and a longitudinal dimension and wherein the longitudinal dimension of the elongated solar cell unit is at least five times greater than a width dimension of the elongated solar cell unit.

25. The elongated solar cell unit of claim 1, wherein the elongated solar cell unit has at least one width dimension and a longitudinal dimension and wherein the longitudinal dimension of the elongated solar cell unit is at least ten times greater than a width dimension of the elongated solar cell unit.

26. The elongated solar cell unit of claim 1, wherein the elongated solar cell unit has at least one width dimension and a longitudinal dimension and wherein the longitudinal dimension of the elongated solar cell unit is at least twenty times greater than a width dimension of the elongated solar cell unit.

27. The elongated solar cell unit of claim 1, wherein the elongated solar cell unit has at least one width dimension and a longitudinal dimension and wherein the longitudinal dimension of the elongated solar cell unit is at least forty times greater than a width dimension of the elongated solar cell unit.

28. A solar cell assembly comprising a plurality of elongated solar cell units, each elongated solar cell unit in the plurality of solar cell units having the structure of the elongated solar cell unit of claim 1, wherein elongated solar cell units in said plurality of elongated solar cell units are arranged in coplanar rows to form said solar cell assembly.

29. The solar cell assembly of claim 28, further comprising an albedo surface positioned to reflect sunlight onto the plurality of elongated solar cell units.

30. The solar cell assembly of claim 29, wherein the albedo surface has an albedo that exceeds 80%.

31. The solar cell assembly of claim 28, wherein a first elongated solar cell unit and a second elongated solar cell unit in the plurality of elongated solar cell units are electrically arranged in series.

32. The solar cell assembly of claim 28, wherein a first elongated solar cell unit and a second elongated solar cell unit in the plurality of elongated solar cell units are electrically arranged in parallel.

33. The elongated solar cell unit of claim 1, wherein the substrate is either (i) tubular shaped or (ii) a rigid solid.

34. The elongated solar cell unit of claim 1, wherein the substrate is characterized by a cross-section bounded by a circular shape, or an n-gon, wherein n is 3 or greater.

35. The elongated solar cell unit of claim 1, wherein the substrate or the transparent casing has a Young's modulus of 20 GPa or greater.

36. The elongated solar cell unit of claim 1, wherein the substrate or the transparent casing has a Young's modulus of 50 GPa or greater.

37. The elongated solar cell unit of claim 1, wherein the substrate or the transparent casing has a Young's modulus of 70 GPa or greater.

38. The elongated solar cell unit of claim 1, wherein the transparent casing comprises a plurality of transparent casing layers including a first transparent casing layer and a second transparent casing layer, and wherein the first transparent casing layer is disposed on said one or more solar cells and the second transparent casing layer is disposed on said first transparent nonplanar casing layer.

39. The elongated solar cell unit of claim 1, wherein said one or more solar cells is a plurality of solar cells that are monolithically integrated.

40. The elongated solar cell unit of claim 1, wherein the first sealant cap is hermetically sealed to the first end of the transparent casing using a butyl rubber.

41. The elongated solar cell unit of claim 40, wherein the butyl rubber includes an active desiccant.

42. The elongated solar cell unit of claim 41, wherein the active desiccant is calcium oxide or barium oxide.

43. A solar cell unit comprising:
(A) a substrate;
(B) one or more bifacial or omnifacial solar cells disposed on the substrate;
(C) a transparent casing disposed onto the one or more bifacial or omnifacial solar cells, the transparent nonplanar casing having a first end and a second end; and
(D) a first sealant cap that is hermetically sealed to the first end of the transparent nonplanar casing.

44. The solar cell unit of claim 43, the solar cell unit further comprising a second sealant cap that is hermetically sealed to the second end of the transparent casing.

45. The solar cell unit of claim 43, wherein the first sealant cap is made of metal, metal alloy, or glass.

46. The solar cell unit of claim 43, wherein the first sealant cap is hermetically sealed to an inner surface or an outer surface of said transparent casing.

47. The solar cell unit of claim 43, wherein the transparent casing is made of borosilicate glass and the first sealant cap is made of KOVAR.

48. The solar cell unit of claim 43, wherein the transparent casing is made of soda lime glass and the first sealant cap is made of a low expansion stainless steel alloy.

49. The solar cell unit of claim 43, wherein the first sealant cap is hermetically sealed to an inner surface or an outer surface of said transparent casing, and wherein said hermetic seal is formed by a continuous strip of sealant.

50. The solar cell unit of claim 49, wherein the continuous strip of sealant is on an inner edge of the first sealant cap, on an outer edge of the first sealant cap, on an outer edge of the transparent casing, or on an inner edge of the transparent casing.

51. The solar cell unit of claim 49, wherein the continuous strip of sealant is formed from glass frit, sol-gel, or ceramic cement.

52. The solar cell unit of claim 43, wherein each solar cell in the one or more bifacial or omnifacial solar cells comprises:
a back-electrode disposed on the substrate;
a semiconductor junction disposed on the back-electrode; and
a transparent conductive layer disposed on the semiconductor junction; and
wherein the first sealant cap is in electrical contact with said back-electrode of a first bifacial or omnifacial solar cell in the one or more bifacial or omnifacial solar cells and wherein said first sealant cap serves as an electrode for said back-electrode.

53. The solar cell unit of claim 43, wherein each bifacial or omnifacial solar cell in the one or more bifacial or omnifacial solar cells comprises:
a back-electrode disposed on the substrate;
a semiconductor junction disposed on the back-electrode; and
a transparent conductive layer disposed on the semiconductor junction; and wherein the first sealant cap is in electrical contact with said transparent conductive layer of a first bifacial or omnifacial solar cell in the one or more bifacial or omnifacial solar cells and wherein said first sealant cap serves as an electrode for said transparent conductive layer.

54. The solar cell unit of claim 43, wherein a bifacial or omnifacial solar cell in the one or more bifacial or omnifacial solar cells comprises:
a back-electrode disposed on the substrate;
a semiconductor junction disposed on the back-electrode; and
a transparent conductive layer disposed on the semiconductor junction; wherein the semiconductor junction comprises a homojunction, a heterojunction, a heteroface junction, a buried homojunction, a p-i-n junction, or a tandem junction.

55. The solar cell unit of claim 43, further comprising a filler layer disposed on said one or more bifacial or omnifacial solar cells, thereby sealing said one or more bifacial or omnifacial solar cells.

56. The solar cell unit of claim 55, wherein the filler layer comprises ethylene vinyl acetate (EVA), silicone, silicone gel, epoxy, polydimethyl siloxane (PDMS), RTV silicone rubber, polyvinyl butyral (PVB), thermoplastic polyurethane (TPU), a polycarbonate, an acrylic, a fluoropolymer, or a urethane.

57. The solar cell unit of claim 43, wherein the water vapor transmission rate of the solar cell unit is 10⁻⁴ g/m²·day or less.

58. The solar cell unit of claim 43, wherein the water vapor transmission rate of the solar cell unit is 10⁻⁵ g/m²·day or less.

59. The solar cell unit of claim 43, wherein the water vapor transmission rate of the solar cell unit is 10⁻⁶ g/m²·day or less.

60. The solar cell unit of claim 43, wherein the water vapor transmission rate of the solar cell unit is 10⁻⁷ g/m²·day or less.

61. The solar cell unit of claim 43, wherein the solar cell unit has at least one width dimension and a longitudinal dimension and wherein the longitudinal dimension of the solar cell unit is at least five times greater than a width dimension of the solar cell unit.

62. The solar cell unit of claim 43, wherein the solar cell unit has at least one width dimension and a longitudinal dimension and wherein the longitudinal dimension of the solar cell unit is at least ten times greater than a width dimension of the solar cell unit.

63. The solar cell unit of claim 43, wherein the solar cell unit has at least one width dimension and a longitudinal dimension and wherein the longitudinal dimension of the solar cell unit is at least twenty times greater than a width dimension of the solar cell unit.

64. The solar cell unit of claim 43, wherein the solar cell unit has at least one width dimension and a longitudinal dimension and wherein the longitudinal dimension of the solar cell unit is at least forty times greater than a width dimension of the solar cell unit.

65. A solar cell assembly comprising a plurality of solar cell units, each solar cell unit in the plurality of solar cell units having the structure of the solar cell unit of claim 1, wherein solar cell units in said plurality of solar cell units are arranged in coplanar rows to form said solar cell assembly.

66. The solar cell assembly of claim 65, further comprising an albedo surface positioned to reflect sunlight onto the plurality of solar cell units.

67. The solar cell assembly of claim 66, wherein the albedo surface has an albedo that exceeds 80%.

68. The solar cell assembly of claim 65, wherein a first solar cell unit and a second solar cell unit in the plurality of solar cell units are electrically arranged in series.

69. The solar cell assembly of claim 65, wherein a first solar cell unit and a second solar cell unit in the plurality of solar cell units are electrically arranged in parallel.

70. The solar cell unit of claim 43, wherein the substrate is either (i) tubular shaped or (ii) a rigid solid.

71. The solar cell unit of claim 43, wherein the substrate is characterized by a cross-section bounded by a circular shape, or an n-gon, wherein n is 3 or greater.

72. The solar cell unit of claim 43, wherein the substrate or the transparent casing has a Young's modulus of 20 GPa or greater.

73. The solar cell unit of claim 43, wherein the substrate or the transparent casing has a Young's modulus of 50 GPa or greater.

74. The solar cell unit of claim 43, wherein the substrate or the transparent casing has a Young's modulus of 70 GPa or greater.

75. The solar cell unit of claim 43, wherein the transparent casing comprises a plurality of transparent casing layers including a first transparent casing layer and a second transparent casing layer, and wherein the first transparent casing layer is disposed on said one or more bifacial or omnifacial solar cells and the second transparent casing layer is disposed on said first transparent nonplanar casing layer.

76. The solar cell unit of claim 43, wherein said one or more bifacial or omnifacial solar cells is a plurality of bifacial or omnifacial solar cells that are monolithically integrated.

77. The solar cell unit of claim 43, wherein the first sealant cap is hermetically sealed to the first end of the transparent casing using a butyl rubber.

78. The solar cell unit of claim 77, wherein the butyl rubber includes an active desiccant.

79. The solar cell unit of claim 78, wherein the active desiccant is calcium oxide or barium oxide.
